(19) United States
(12) Patent Application Publication
(10) Pub. No.: US 2026/0033320 A1
(43) Pub. Date: Jan. 29, 2026

(54) THREE-DIMENSIONAL MEMORY DEVICE WITH SLANTED STEPS IN A STAIRCASE REGION AND METHOD OF FORMING THE SAME

(71) Applicant: SANDISK TECHNOLOGIES LLC, ADDISON, TX (US)

(72) Inventors: Akihiro TOBIOKA, Yokkaichi (JP); Takuya TSUDA, Yokkaichi (JP)

(21) Appl. No.: 18/787,247

(22) Filed: Jul. 29, 2024

(51) Int. Cl. H01L 23/528; G11C 16/04; H01L 23/522; H10B 41/10; H10B 41/27; H10B 41/35; H10B 43/10; H10B 43/27; H10B 43/35

(52) U.S. Cl. CPC H01L 23/5283; G11C 16/0483; H01L 23/5226; H10B 41/10; H10B 41/27; H10B 41/35; H10B 43/10; H10B 43/27; H10B 43/35

(57) ABSTRACT

A three-dimensional memory device includes an alternating stack of insulating layers and electrically conductive layers, the alternating stack having a pair of lengthwise sidewalls that laterally extend along a first horizontal direction and having stepped surfaces in a staircase region, memory openings vertically extending through a memory array region of the alternating stack in which each layer within the alternating stack is present, and memory opening fill structures in the memory openings. Each of the memory opening fill structures includes a vertical stack of memory elements and a vertical semiconductor channel. The stepped surfaces in the staircase region include first vertical steps laterally extending along a first lateral direction which is at an acute angle relative to the first horizontal direction in a plan view along a vertical direction.

### FIELD

The present disclosure relates generally to the field of semiconductor devices, and particularly to a three-dimensional memory device containing slanted steps in a staircase region and method of forming the same.

### BACKGROUND

A three-dimensional memory device including three-dimensional vertical NAND strings having one bit per cell is disclosed in an article by T. Endoh et al, titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device comprises: an alternating stack of insulating layers and electrically conductive layers, the alternating stack having a pair of lengthwise sidewalls that laterally extend along a first horizontal direction and having stepped surfaces in a staircase region; memory openings vertically extending through a memory array region of the alternating stack in which each layer within the alternating stack is present; and memory opening fill structures in the memory openings, wherein each of the memory opening fill structures comprises a vertical stack of memory elements and a vertical semiconductor channel, wherein the stepped surfaces in the staircase region comprise first vertical steps laterally extending along a first lateral direction which is at an acute angle relative to the first horizontal direction in a plan view along a vertical direction.

According to another aspect of the present disclosure, a method of forming a three-dimensional memory device comprises: forming an alternating stack of insulating layers and spacer material layers over a substrate, wherein the spacer material layers are formed as, or are subsequently replaced with, electrically conductive layers; forming stepped surfaces in a staircase region by patterning the alternating stack, wherein the staircase region is laterally bounded by a staircase-region sidewall laterally extending along a first horizontal direction and having a stepped bottom surface that adjoins edges of stepped surfaces, and wherein the stepped surfaces comprise first vertical steps laterally extending along a first lateral direction which is at an acute angle relative to the first horizontal direction in a plan view along a vertical direction forming memory openings through a memory array region of the alternating stack in which each layer within the alternating stack is present; and forming memory opening fill structures in the memory openings, wherein each of the memory opening fill structures comprises a vertical stack of memory elements and a vertical semiconductor channel.

### BRIEF DESCRIPTION OF THE DRAWINGS

FIG. 1 is a plan view of an exemplary semiconductor die including multiple three-dimensional memory array regions according to an embodiment of the present disclosure.

FIG. 2 is a vertical cross-sectional view of region M1 in FIG. 1 of an exemplary structure for forming the semiconductor die after formation of optional semiconductor devices, optional lower level dielectric layers, optional lower metal interconnect structures, a semiconductor material layer, and an alternating layer stack of insulating layers and sacrificial material layers according to a first embodiment of the present disclosure.

FIG. 3A is a vertical cross-sectional view of the exemplary structure after formation of stepped cavities according to a first embodiment of the present disclosure. FIG. 3B is a top-down cross-sectional view of the exemplary structure of FIG. 3A. The vertical plane A-A′ is the cut plane of the vertical cross-sectional view of FIG. 3A. FIG. 3C is a vertical cross-sectional view along the vertical plane C-C′ of FIG. 3B.

FIG. 4A is a vertical cross-sectional view of a region of the exemplary structure after performing a first anisotropic etch process for patterning stepped surfaces according to a first embodiment of the present disclosure. FIG. 4B is a top-down view of the region of the exemplary structure of FIG. 4A.

FIG. 5A is a vertical cross-sectional view of a region of the exemplary structure after performing a second anisotropic etch process for patterning stepped surfaces according to the first embodiment of the present disclosure. FIG. 5B is a top-down view of the region of the exemplary structure of FIG. 5A.

FIG. 6A is a vertical cross-sectional view of a region of the exemplary structure after performing a third anisotropic etch process for patterning stepped surfaces according to the first embodiment of the present disclosure. FIG. 6B is a top-down view of the region of the exemplary structure of FIG. 6A.

FIG. 7A is a vertical cross-sectional view of a region of the exemplary structure after performing a first anisotropic etch process employing a first alternative pattern for a first etch mask layer according to a first embodiment of the present disclosure. FIG. 7B is a top-down view of the region of the exemplary structure of FIG. 7A.

FIG. 8A is a vertical cross-sectional view of a region of the exemplary structure after performing a first anisotropic etch process employing a second alternative pattern for a first etch mask layer according to a first embodiment of the present disclosure. FIG. 8B is a top-down view of the region of the exemplary structure of FIG. 8A.

FIG. 9A is a vertical cross-sectional view of a region of the exemplary structure after performing a first anisotropic etch process for patterning stepped surfaces according to a second embodiment of the present disclosure. FIG. 9B is a top-down view of the region of the exemplary structure of FIG. 9A.

FIG. 10A is a vertical cross-sectional view of a region of the exemplary structure after performing a second anisotropic etch process for patterning stepped surfaces according to the second embodiment of the present disclosure. FIG. 10B is a top-down view of the region of the exemplary structure of FIG. 10A.

FIG. 11A is a vertical cross-sectional view of a region of the exemplary structure after performing a third anisotropic etch process for patterning stepped surfaces according to the second embodiment of the present disclosure. FIG. 11B is a top-down view of the region of the exemplary structure of FIG. 11A.

FIG. 12A is a vertical cross-sectional view of a region of the exemplary structure after performing a fourth anisotropic etch process for patterning stepped surfaces according to the second embodiment of the present disclosure. FIG. 12B is a top-down view of the region of the exemplary structure of FIG. 12A.

FIG. 13 is a perspective view of a region of the exemplary structure after formation of stepped surfaces according to an embodiment of the present disclosure.

FIG. 14A is a vertical cross-sectional view of the exemplary structure after formation of retro-stepped dielectric material portions according to an embodiment of the present disclosure. FIG. 14B is a top-down cross-sectional view of the exemplary structure of FIG. 14A. The vertical plane A-A′ is the cut plane of the vertical cross-sectional view of FIG. 14A.

FIG. 15A is a vertical cross-sectional view of the exemplary structure after formation of support pillar structures according to an embodiment of the present disclosure.

FIG. 15B is a top-down cross-sectional view of the exemplary structure of FIG. 15A. The vertical plane A-A′ is the cut plane of the vertical cross-sectional view of FIG. 15A.

FIG. 16A is a vertical cross-sectional view of the exemplary structure after formation of memory openings according to an embodiment of the present disclosure. FIG. 16B is a top-down cross-sectional view of the exemplary structure of FIG. 16A. The vertical plane A-A′ is the cut plane of the vertical cross-sectional view of FIG. 16A.

FIGS. 17A-17F are sequential vertical cross-sectional views of a region around a memory opening during formation of a memory opening fill structure according to an embodiment of the present disclosure.

FIG. 18A is a vertical cross-sectional view of the exemplary structure after formation of memory opening fill structures according to an embodiment of the present disclosure. FIG. 18B is a top-down cross-sectional view of the exemplary structure of FIG. 18A. The vertical plane A-A′ is the cut plane of the vertical cross-sectional view of FIG. 18A.

FIG. 19A is a vertical cross-sectional view of the exemplary structure after formation of lateral isolation trenches according to an embodiment of the present disclosure.

FIG. 19B is a top-down cross-sectional view of the exemplary structure of FIG. 19A. The vertical plane A-A′ is the cut plane of the vertical cross-sectional view of FIG. 19A. FIG. 19C is a vertical cross-sectional view along the vertical plane C-C′ of FIG. 19B.

FIG. 20A is a vertical cross-sectional view of the exemplary structure after replacement of sacrificial material layers with electrically conductive layers according to an embodiment of the present disclosure. FIG. 20B is a top-down cross-sectional view of the exemplary structure of FIG. 20A. The vertical plane A-A′ is the cut plane of the vertical cross-sectional view of FIG. 20A. FIG. 20C is a horizontal cross-sectional view of the exemplary structure along the horizontal plane C-C′ of FIG. 20B.

FIG. 21A is a vertical cross-sectional view of the exemplary structure after formation of lateral isolation trench fill structures according to an embodiment of the present disclosure. FIG. 21B is a top-down cross-sectional view of the exemplary structure of FIG. 21A. The vertical plane A-A′ is the cut plane of the vertical cross-sectional view of FIG. 21A. FIG. 20C is a horizontal cross-sectional view of the exemplary structure along the horizontal plane C-C′ of FIG. 21B.

FIG. 22A is a vertical cross-sectional view of the exemplary structure after formation of contact via structures according to an embodiment of the present disclosure.

FIG. 22B is a top-down cross-sectional view of the exemplary structure of FIG. 22A. The vertical plane A-A′ is the cut plane of the vertical cross-sectional view of FIG. 22A. FIG. 22C is a vertical cross-sectional view of the exemplary structure along the vertical plane C-C′ of FIG. 22B. FIG. 22D is a perspective view of a region of the exemplary structure of FIGS. 22A-22C.

FIG. 23A is a top-down view of a first configuration of the exemplary structure.

FIG. 23B is a top-down view of a second configuration of the exemplary structure.

FIG. 24A is a top-down view of a third configuration of the exemplary structure.

FIG. 24B is a vertical cross-sectional view of the third configuration of the exemplary structure along the hinged vertical plane B-B′ of FIG. 24A.

FIG. 25A is a top-down view of a fourth configuration of the exemplary structure.

FIG. 25B is a top-down view of a fifth configuration of the exemplary structure.

FIG. 26 is a schematic diagram illustrating non-congruence of stepped bottom edges of the staircase-region sidewalls of a retro-stepped dielectric material portion according to an embodiment of the present disclosure.

### DETAILED DESCRIPTION

As discussed above, the embodiments of the present disclosure are directed to a three-dimensional memory device containing slanted steps in a staircase region and methods of forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁵ S/m to 1.0×10⁵ S/m. As used herein, a “semiconductor material” refers to a material having electrical conductivity in the range from 1.0×10⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopants at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which may be the smallest unit that may be erased by in a single erase operation. Each memory block contains a number of pages, which are the smallest units that may be selected for programming. A page is also the smallest unit that may be selected to a read operation.

According to an aspect of the present disclosure, stepped surfaces of electrically conductive layers can be formed in a staircase region such that vertical steps of the stepped surfaces are diagonal (i.e., not orthogonal) to the general ascension/descension direction of the stepped surfaces. The tilted vertical steps of the stepped surfaces can be employed to facilitate formation of multi-lane layer contact via structures for contacting the electrically conductive layers in the staircase region.

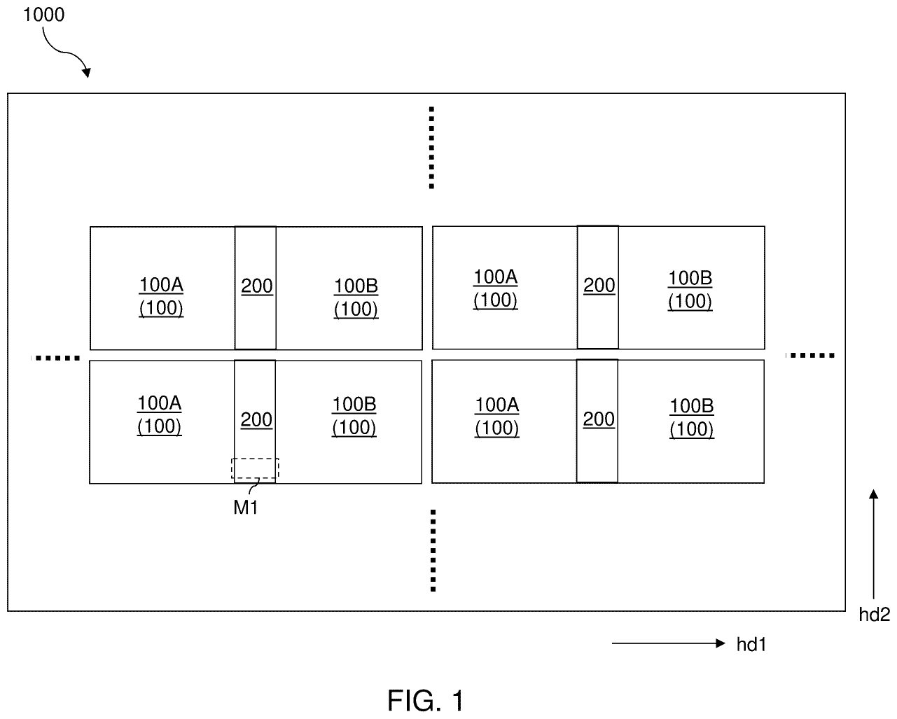

Referring to FIG. 1, an exemplary semiconductor die 1000 according to an embodiment of the present disclosure is illustrated. The exemplary semiconductor die 1000 includes multiple three-dimensional memory array regions and multiple inter-array regions. The exemplary semiconductor die 1000 can include multiple planes, each of which includes two memory array regions 100, such as a first memory array region 100A and a second memory array region 100B that are laterally spaced apart by a respective inter-array region 200. Generally, a semiconductor die 1000 may include a single plane or multiple planes. The total number of planes in the semiconductor die 1000 may be selected based on performance requirements on the semiconductor die 1000. A pair of memory array regions 100 in a plane may be laterally spaced apart along a first horizontal direction hd1 (which may be the word line direction). For example, each pair of memory array regions 100 in a plane may include first memory array region 100A and a second memory array region 100B that are laterally spaced apart along the first horizontal direction hd1 by an inter-array region 200. A second horizontal direction hd2 (which may be the bit line direction) can be perpendicular to the first horizontal direction hd1.

The exemplary semiconductor die 1000 of FIG. 1 can be manufactured employing various embodiments of the present disclosure to be described below. An exemplary structure is employed to provide exemplary sequences of processing steps for forming the exemplary semiconductor die 1000 of FIG. 1.

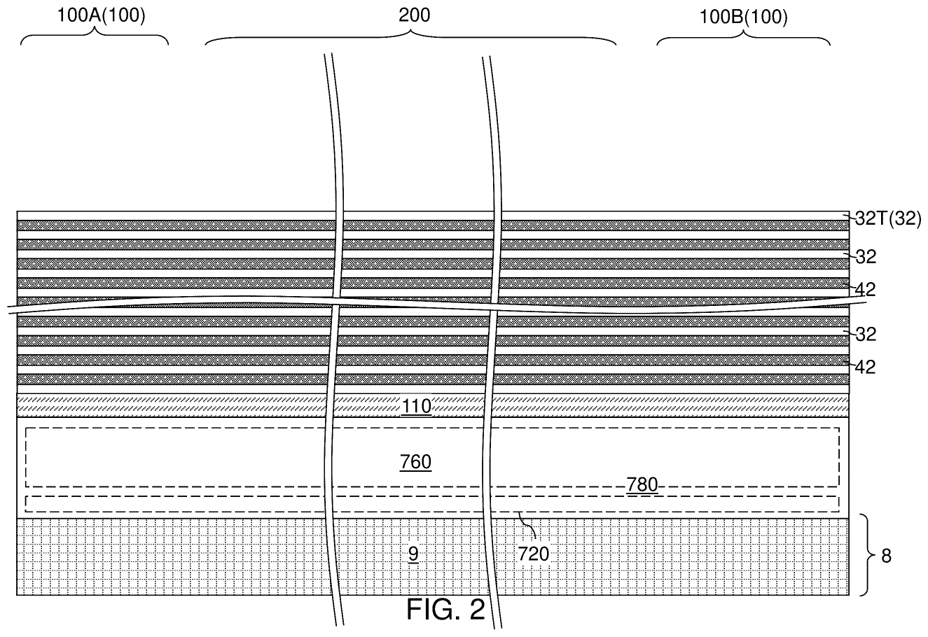

Referring to FIG. 2, an exemplary structure is illustrated, which comprises a substrate 8 including a substrate semiconductor layer 9. The substrate 8 may be a single crystalline silicon wafer, a silicon on insulator (SOI) substrate, or an insulating (e.g., glass or quartz) substrate. The substrate semiconductor layer 9 may be a single crystalline semiconductor material layer such as a single crystalline silicon layer that is epitaxially grown on a silicon wafer or SOI substrate, or a doped well in an upper portion of a silicon wafer or SOI substrate. Semiconductor devices 720 can be formed on the top surface of the substrate semiconductor layer 9. For example, the semiconductor devices 720 may include field effect transistors, resistors, capacitors, diodes, and/or various other semiconductor devices known in the art. In one embodiment, the semiconductor devices 720 may include a peripheral (i.e., driver) circuit for controlling the operation of three-dimensional memory arrays to be subsequently formed thereabove. Metal interconnect structures embedded in dielectric material layers may be formed above the semiconductor devices. The metal interconnect structures are herein referred to as lower-level metal interconnect structures 780, and the dielectric material layers are herein referred to as lower-level dielectric material layers 760. The lower-level metal interconnect structures 780 are electrically connected to various nodes of the semiconductor devices 720, and can include metal line structures and metal via structures located at various levels of the lower-level dielectric material layers 760.

A semiconductor material layer 110 can be formed on the top surface of the lower-level dielectric material layers 760. The semiconductor material layer 110 may be single crystalline or polycrystalline, and may be formed by a layer transfer from a source substrate (such as a single crystalline silicon layer including a buried hydrogen implantation layer), or may be formed by deposition of a semiconductor material (which may be a polycrystalline semiconductor material, such as polysilicon).

An alternating stack (32, 42) of insulating layers 32 and spacer material layers can be formed over the semiconductor material layer 110. Generally, the spacer material layers are formed as, or are subsequently replaced with, electrically conductive layers. In one embodiment, the spacer material layers may be formed as sacrificial material layers 42 that are subsequently replaced with electrically conductive layers. While an embodiment is described in which the spacer material layers are formed as sacrificial material layers 42, in other embodiments the spacer material layers are formed as electrically conductive layers. In this case, a set of processing steps employed to replace the sacrificial material layers 42 with electrically conductive layers may be omitted.

In one embodiment, an alternating stack of insulating layers 32 and sacrificial material layers 42 can be formed over the semiconductor material layer 110. As used herein, the term “alternating stack” refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element. An alternating stack refers to a sequence of multiple instances of a first material layer and multiple instances of a second material layer such that the instances of the first material layer and the instances of the second material layer are interlaced.

The insulating layers 32 can be composed of the first material, and the sacrificial material layers 42 can be composed of the second material, which is different from the first material. Each of the insulating layers 32 continuously extends over the entire area of the substrate 8, and may have a uniform thickness throughout. Each of the sacrificial material layers 42 includes a sacrificial dielectric material and continuously extends over the entire area of the substrate 8, and may have a uniform thickness throughout. Insulating materials that may be used for the insulating layers 32 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 may be silicon oxide.

The second material of the sacrificial material layers 42 is a dielectric material, which is a sacrificial material that may be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material. The second material of the sacrificial material layers 42 may be subsequently replaced with electrically conductive electrodes which may function, for example, as control gate electrodes of a vertical NAND device. In one embodiment, the sacrificial material layers 42 may be material layers that comprise silicon nitride.

Each insulating layer 32 may have a first thickness, which may be in a range from 15 nm to 60 nm, although lesser and greater thicknesses may also be employed. Each sacrificial material layer 42 may have a second thickness, which may be in a range from 15 nm to 60 nm, although lesser and greater thicknesses may also be employed. The total number of repetitions of a pair of an insulating layer 32 and a sacrificial material layer 42 in the alternating stack (32, 42) may be in a range from 16 to 1,024, such as from 64 to 512, although lesser and greater numbers may also be employed. The topmost layer among the insulating layers 32 is herein referred to as a topmost insulating layer 32T.

In an alternative embodiment, the semiconductor devices 720, the lower-level metal interconnect structures 780, and the lower-level dielectric material layers 760 may be located next to the alternating stack (32, 42) over the substrate 8 rather than underneath the alternating stack (32, 42). In yet another alternative embodiment, the semiconductor devices 720, the lower-level metal interconnect structures 780, and the lower-level dielectric material layers 760 may be omitted, i.e., not formed over the substrate 8. Instead, the semiconductor devices 720 of the peripheral (i.e., driver) circuit may be formed over a separate substrate and then bonded over the three-dimensional memory device. Optionally, the semiconductor material layer 110 may also be omitted in case the substrate 8 is later removed and a top source contact layer is formed on an exposed surface of the memory device, or it may be modified to function as part of a lateral source contact (e.g., direct strap contact) which is subsequently formed under the alternating stack.

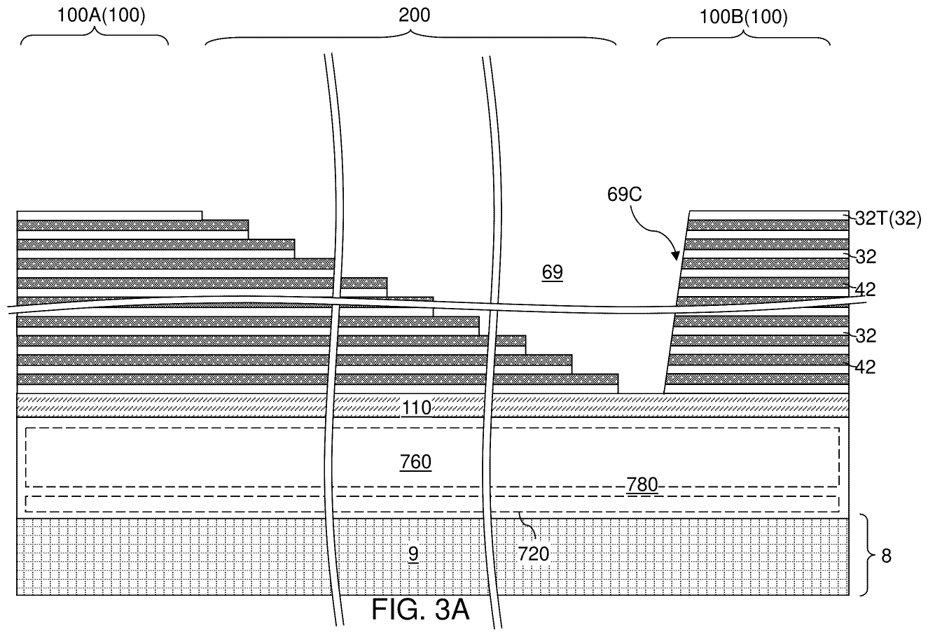

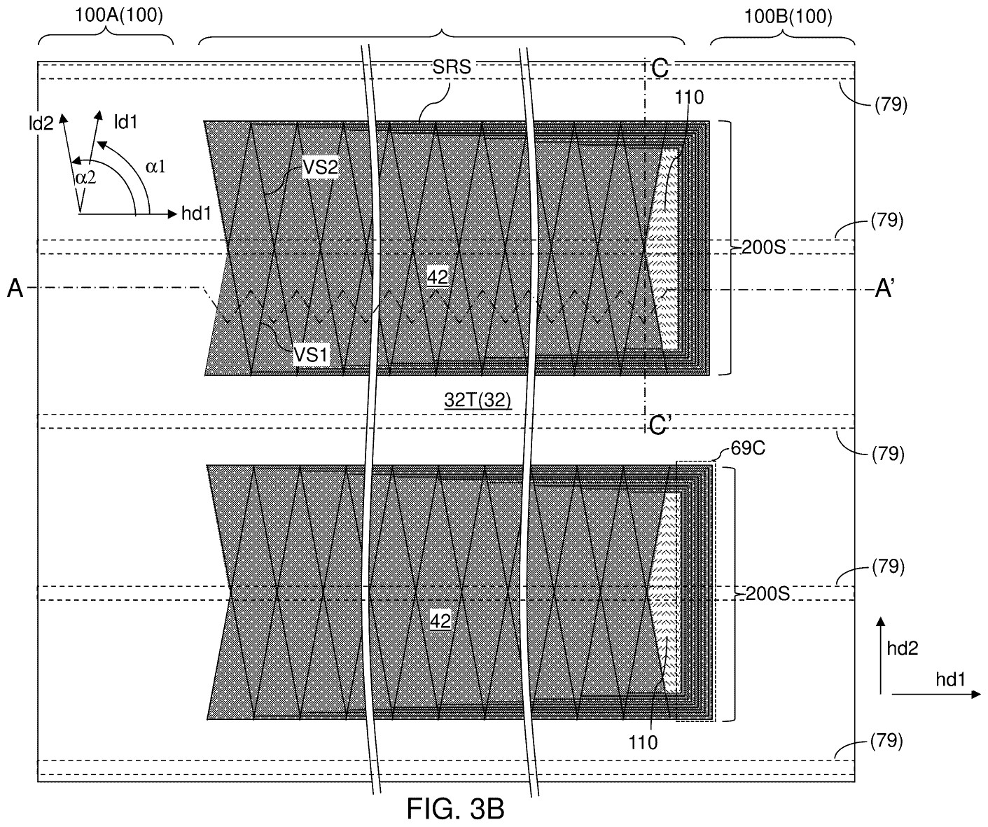

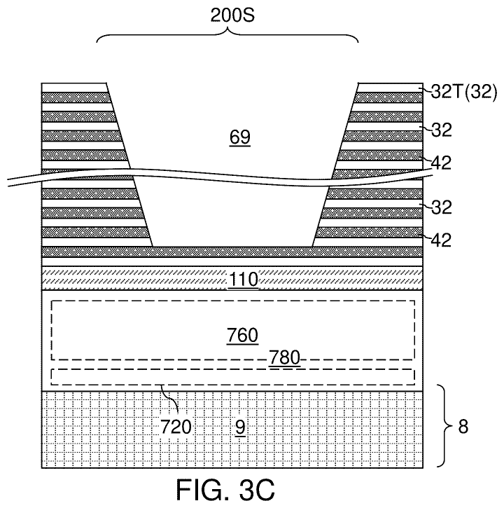

Referring to FIGS. 3A-3C, stepped surfaces can be formed within the inter-array regions 200 using multiple patterning steps. A stepped cavity 69 can be formed within each of the staircase regions 200S. Each staircase region 200S is an area within the inter-array region 200 in which stepped surfaces are formed. Each stepped cavity 69 can include a cliff region 69C in which a tapered sidewall of the alternating stack (32, 42) vertically extends from the bottommost layer of the alternating stack (32, 42) to the topmost layer of the alternating stack (32, 42). Generally, each stepped cavity 69 can be formed with a pair of lengthwise sidewalls, which is herein referred to as a pair of staircase-region sidewalls SRS. Generally, lateral isolation trenches 79 are formed through the alternating stack (32, 42) at a subsequent processing step that is performed after the processing steps that form the exemplary structure illustrated in FIGS. 3A-3C. The areas of the lateral isolation trenches 79 to be subsequently formed are represented as dotted rectangles in FIG. 3B. The lateral isolation trenches 79 to be subsequently formed laterally extend along a first horizontal direction (e.g., word line direction) hd1. In one embodiment, the lateral isolation trenches 79 may be subsequently formed as a periodic one-dimensional array having a uniform pitch along a second horizontal direction (e.g., bit line direction) hd2 that is perpendicular to the first horizontal direction hd1.

Each stepped cavity 69 has stepped surfaces, i.e., a set of horizontally extending surface segments and vertical steps (VS1, VS2) that are adjoined among one another. According to an aspect of the present disclosure, the vertical steps of the stepped surfaces of each stepped cavity 69 comprises first vertical steps VS1 that laterally extend along a first lateral direction ld1 that is not parallel to and is not orthogonal to (i.e., not perpendicular to), the first horizontal direction hd1, and second vertical steps VS2 that laterally extend along a second lateral direction ld2 that is not parallel to and is not orthogonal to the first horizontal direction hd1. In one embodiment, the angle between the first lateral direction ld1 and the first horizontal direction hd1 in a plan view along the vertical direction may be an acute angle a1 (which is also referred to as a first angle), and the angle between the second lateral direction ld2 and the first horizontal direction hd1 in the plan view may be an obtuse angle a2 (which is also referred to as a second angle). The value of the acute angle a1 may be in a range from 30 degrees to 80 degrees, such as from 45 degrees to 60 degrees, and the value of the obtuse angle may be in a range from 100 degrees to 150 degrees, such as from 120 degrees to 145 degrees.

Each stepped cavity 69 has a pair of stepped sidewalls that laterally extend along the first horizontal direction hd1. The pair of stepped sidewalls is herein referred to as a pair of staircase-region sidewalls SRS. Each stepped sidewall of the stepped cavity 69 adjoins the stepped surfaces at the bottom edge, and extends to the top surface of the topmost layer of the alternating stack (32, 42). Generally, the stepped cavities 69 can be formed by patterning the alternating stack (32, 42) in each inter-array region 200, which is located between a respective first memory array region 100A and a second memory array region 100B.

In one embodiment, each stepped cavity 69 may be formed such that the geometrical center of an area of the stepped cavity 69 is formed within the area of a respective lateral isolation trench 79 to be subsequently formed. In this case, each stepped cavity 69 may be formed such that the area of each stepped cavity 69 has an areal overlap with a respective lateral isolation trench 79 to be subsequently formed, and does not have any areal overlap with any other lateral isolation trenches 79 to be subsequently formed. Alternatively, each stepped cavity 69 may be formed between the areas of a respective neighboring pair of lateral isolation trenches 79 to be subsequently formed. In this case, the stepped cavities 69 do not have any areal overlap with the areas of the lateral isolation trenches 79 to be subsequently formed.

In one embodiment, the horizontal surface segments of the stepped surfaces within each stepped cavity 69 may comprise two rows of triangular horizontal surface segments (i.e., horizontal surface segments having a respective triangular shape in a plan view such as a top-down view) and a row of parallelogram-shaped horizonal surface segments located between the two rows of triangular horizontal surface segments.

In summary, stepped surfaces can be formed in each staircase region 200S by patterning the alternating stack (32, 42). Each staircase region is laterally bounded by a pair of staircase-region sidewalls SRS. Each of the staircase-region sidewalls SRS laterally extends along a first horizontal direction hd1, and has a respective stepped bottom surface that adjoins edges of stepped surfaces of the stepped cavity 69. In one embodiment, the stepped surfaces comprise first vertical steps VS1 laterally extending along a first lateral direction ld1 which is at an acute angle a1 relative to the first horizontal direction hd1 in a plan view along a vertical direction, and comprise second vertical steps VS2 laterally extending along a second lateral direction ld2 which is at an obtuse angle a2 relative to the first horizontal direction hd1 in the plan view along the vertical direction.

In some embodiments, each of the multiple patterning steps may comprise a combination of a respective photoresist patterning process and a respective anisotropic etch process. Each photoresist patterning process may comprise a photoresist material application step that applies a blanket photoresist material layer, a lithographic exposure step that lithographically exposes the blanket photoresist material layer, and a lithographic development step that forms a patterned photoresist layer. Each anisotropic etch process may transfer the pattern in the patterned photoresist layer through a respective number of pairs of a sacrificial material layer 42 and an insulating layer 32. The patterned photoresist layer may be subsequently removed after the anisotropic etch process. In one embodiment, the numbers of pairs of a sacrificial material layer 42 and an insulating layer 32 may be different among the anisotropic etch processes of the multiple patterning steps. For example, the numbers of pairs of a sacrificial material layer 42 and an insulating layer 32 may be non-negative integer powers of 2, such as 1, 2, 4, 8, 16, 32, 64, etc.

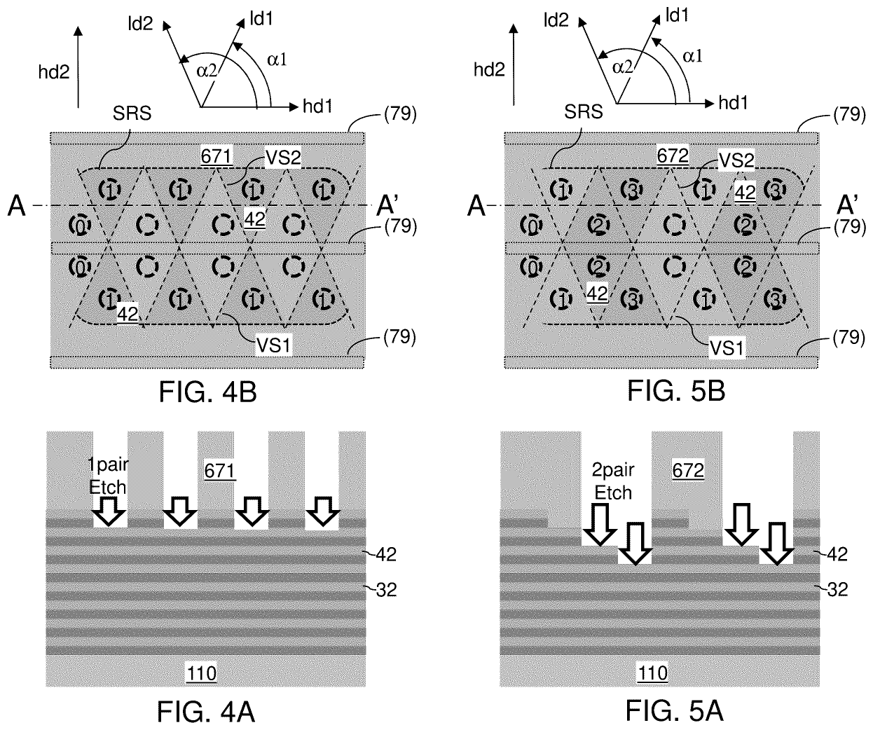

FIGS. 4A-8B illustrate a steps of a method according to a first embodiment of forming stepped cavities 69 by combinations of a respective photoresist patterning process and a respective anisotropic etch process. The numbers within dotted circles represent the number of pairs of a sacrificial material layer 42 and an insulating layer 32 that are removed from a respective area. Dotted circles without any number therein represent areas in which the alternating stack (32, 42) is not etched by any anisotropic etch process.

Referring to FIGS. 4A and 4B, a region of the exemplary structure is illustrated after performing a first anisotropic etch process for patterning stepped surfaces according to the first embodiment of the present disclosure. In this case, a first photoresist layer 671 can be applied over the alternating stack (32, 42), and can be lithographically patterned to form openings such that the edges of the openings in the first photoresist layer 671 include patterns for forming first vertical steps VS1 and second vertical steps VS2 upon pattern transfer into a subset of layers in the alternating stack (32, 42). In the illustrative example, the pattern of the openings in the first photoresist layer 671 may comprise two rows of triangular openings. The pattern of the first vertical steps VS1 and second vertical steps VS2 can be formed by two sets of parallel line patterns, i.e., a set of line patterns that are parallel to the first lateral direction ld1 and a set of line patterns that are parallel to the second lateral direction ld2. Unmasked portions of 2ⁱ pair(s) of a sacrificial material layer 42 and an insulating layer 32 may be etched by performing a first anisotropic etch process, where i may be any non-negative integer (i.e., zero or any positive integer). In the illustrated example, the integer i is 0 for the first anisotropic etch process. The first photoresist layer 671 can be subsequently removed, for example, by ashing.

Referring to FIGS. 5A and 5B, a second photoresist layer 672 can be applied over the alternating stack (32, 42), and can be lithographically patterned to form openings such that the edges of the openings in the second photoresist layer 672 coincide with a subset of the first vertical steps VS1 and second vertical steps VS2 in a plan view such as a top-down view. In an illustrative example, the pattern of the openings in the second photoresist layer 672 may comprise a row of chevron-shaped openings that are laterally spaced apart along the first horizontal direction hd1. Unmasked portions of 2j pair(s) of a sacrificial material layer 42 and an insulating layer 32 may be etched by performing a second anisotropic etch process. The integer j may be any non-negative integer. In the illustrated example, the integer j is 1 for the second anisotropic etch process. The second photoresist layer 672 can be subsequently removed, for example, by ashing.

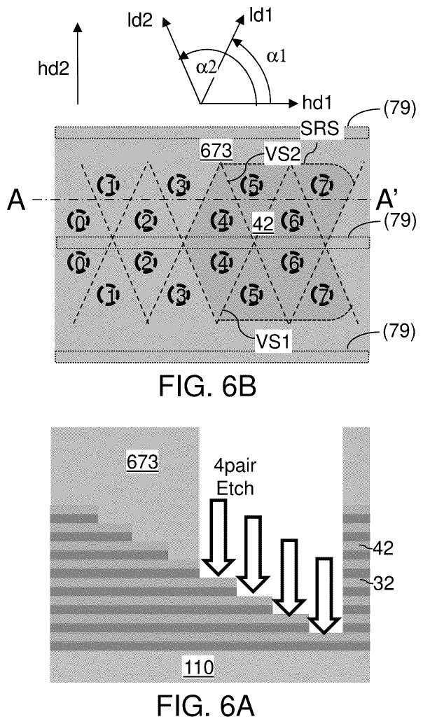

Referring to FIGS. 6A and 6B, a third photoresist layer 673 can be applied over the alternating stack (32, 42), and can be lithographically patterned to form openings such that the edges of the openings in the third photoresist layer 673 coincide with a subset of the first vertical steps VS1 and second vertical steps VS2 in a plan view such as a top-down view. In the illustrative example, the pattern of the openings in the third photoresist layer 673 may comprise at least one chevron-shaped opening. Unmasked portions of 2k pair(s) of a sacrificial material layer 42 and an insulating layer 32 may be etched by performing a third anisotropic etch process. The integer k may be any non-negative integer. In the illustrated example, the integer k is 2 for the third anisotropic etch process. The third photoresist layer 673 can be subsequently removed, for example, by ashing.

Generally, the patterns of the openings in the various photoresist layers (671, 672, 673) can be selected such that the depth of the horizontal surface segments of the stepped surfaces that are formed in each staircase region increases stepwise along the first horizontal direction hd1. Further, the patterns of the openings in the various photoresist layers (671, 672, 673) can be selected such that each sacrificial material layer 42 that is vertically spaced from the horizontal plane including the topmost layer of the alternating stack (32, 42) by a vertical distance that is less than the maximum recess distance of the stepped surfaces comprises a horizontal surface segment that is a component of the stepped surfaces. The processing steps described with reference to FIGS. 4A-6B may be repeated as many times as needed with suitable modifications to form stepped surfaces in each staircase regions such that each of the sacrificial material layers 42 comprises a respective horizontal surface segment that is a component of the stepped surfaces that underlie the stepped cavity 69.

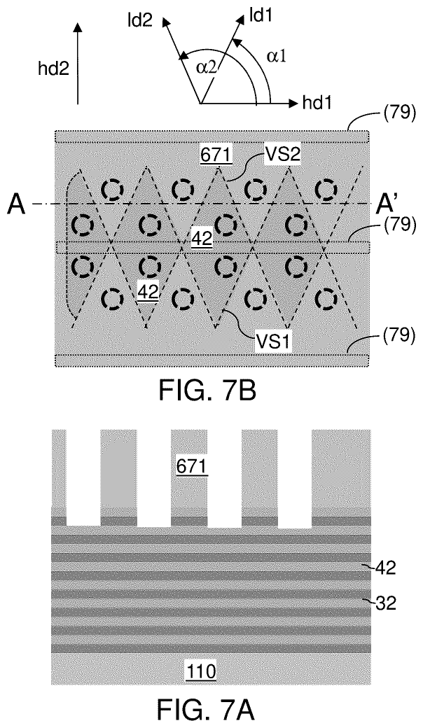

Referring to FIGS. 7A and 7B, a first alternative pattern for the first photoresist layer 671 is illustrated, which may be employed in lieu of the pattern described with reference to FIGS. 4A and 4B. Specifically, the areas of the openings and the areas covered by the first photoresist layer 671 are reversed within the area of the stepped cavity 69 to be subsequently formed. The difficulty of lithographic patterning may be reduced because patterning a larger parallelogram-shaped area tends to be easier than patterning a smaller triangular area. Subsequently, the processing steps described with reference to FIGS. 5A, 5B, 6A, and 6B may be performed.

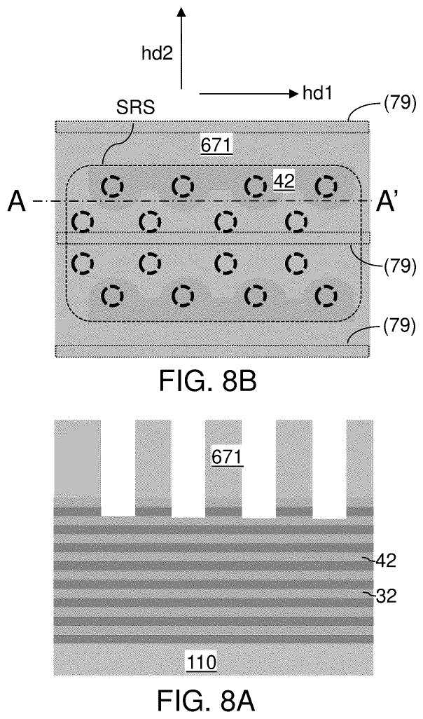

Referring to FIGS. 8A and 8B, a second alternative pattern for the first photoresist layer 671 is illustrated, which may be employed in lieu of the pattern described with reference to FIGS. 4A and 4B. Specifically, the shapes of the areas of the openings in the first photoresist layer 671 may be rounded to avoid patterning sharp corners with small dimensions. Subsequently, the processing steps described with reference to FIGS. 5A, 5B, 6A, and 6B may be performed.

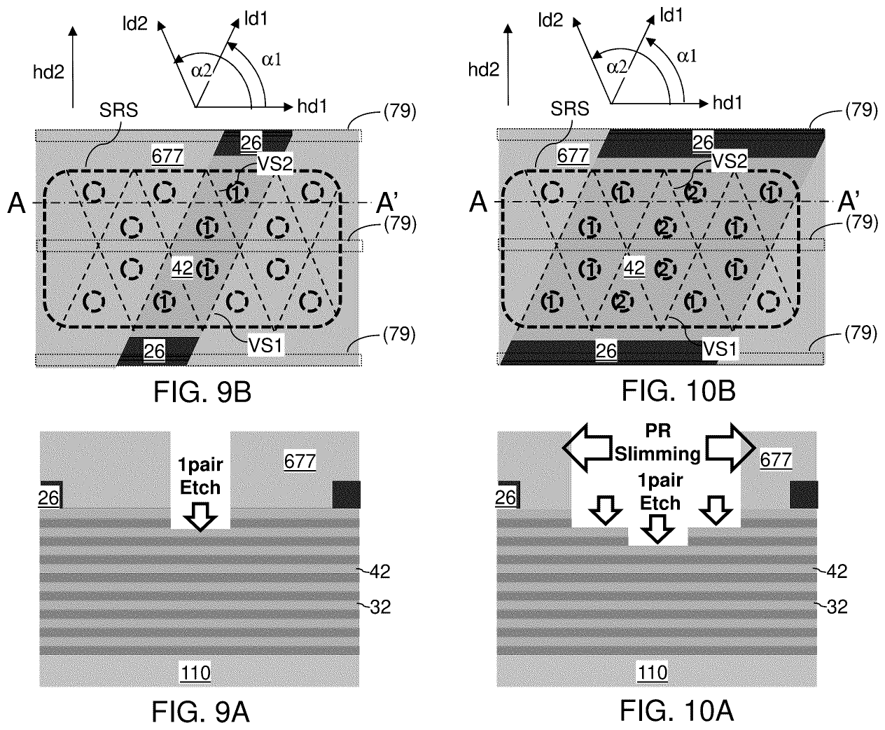

In a second embodiment, a combination of a hard mask layer and a pair of trimmable photoresist layers may be used instead of the plurality of photoresist layers described with reference to the method of the first embodiment illustrated in FIGS. 4A-8B. FIGS. 9A-12B illustrate the method of the second embodiment in which the stepped cavities 69 are formed employing the hard mask layer 26 and a pair of trimmable photoresist layers (677, 679). In FIGS. 9A-12B, the numbers within dotted circles represent the number of pairs of a sacrificial material layer 42 and an insulating layer 32 that are removed from a respective area. Dotted circles without any number therein represent areas in which the alternating stack (32, 42) is not etched by any anisotropic etch process.

Referring to FIGS. 9A and 9B, a hard mask layer 26 can be formed over the alternating stack (32, 42). The hard mask layer 26 may comprise any suitable hard mask layer material, such as a semiconductor (e.g., polysilicon or amorphous silicon), a metal, a metal nitride, a metal oxide, silicon oxycarbide, silicon carbonitride, etc., which has a higher etch resistance to the etchant(s) used to pattern the insulating layers 32 and the sacrificial material layers. The hard mask layer 26 can be patterned to provide openings, which are formed within the areas of the stepped cavities 69 to be subsequently formed. In other words, the areas of the openings in the hard mask layer 26 define the areas of the stepped cavities 69 to be subsequently formed. A first trimmable photoresist layer 677 can be applied over the hard mask layer 26, and can be lithographically patterned to form an initial slit-shaped opening. The first trimmable photoresist layer 677 includes a trimmable photoresist material, i.e., a photoresist material that allows slow ashing such that the photoresist material can be isotropically recessed at a controlled rate. According to an aspect of the present disclosure, the two edges of the initial slit-shaped openings may coincide with the locations of a pair of first vertical steps VS1 to be subsequently formed in a plan view such as a top-down view. Unmasked portions of the alternating stack (32, 42) may be etched by a pair a sacrificial material layer 42 and an insulating layer 32 by performing a first anisotropic etch process. After the processing steps of FIGS. 9A and 9B, two first vertical steps VS1 can be patterned in the alternating stack (32, 42). FIG. 9B illustrates the locations of all first vertical steps VS1 and all second vertical steps VS2 that are formed at the processing steps of FIGS. 9A and 9B or that are to be subsequently formed.

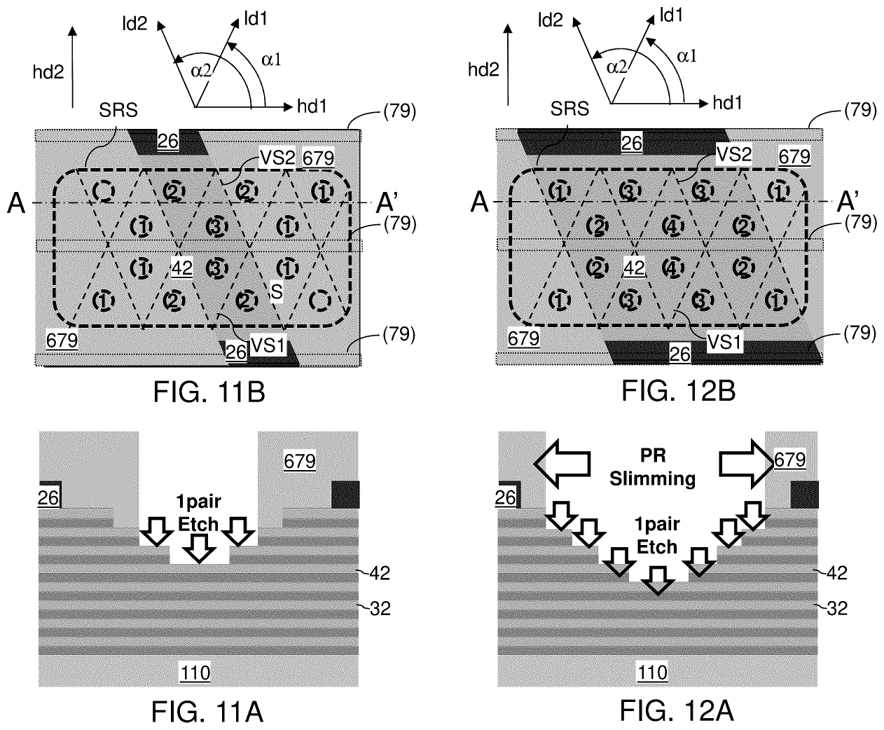

Referring to FIGS. 10A and 10B, the first trimmable photoresist layer 677 can be trimmed (i.e., slimmed) by performing a controlled ashing process. The lateral trimming distance can be selected such that the straight edges of the first trimmable photoresist layer 677 after the trimming process are formed at locations of two first vertical steps VS1, which are neighboring first vertical steps VS1 with respect to the two vertical steps VS1 that are formed at the processing steps of FIGS. 9A and 9B. Unmasked portions of the alternating stack (32, 42) may be etched by a pair a sacrificial material layer 42 and an insulating layer 32 by performing a second anisotropic etch process. After the processing steps of FIGS. 10A and 10B, four first vertical steps VS1 can be patterned in the alternating stack (32, 42). FIG. 10B illustrate the locations of all first vertical steps VS1 and all second vertical steps VS2 that are present upon completion of the processing steps of FIGS. 10A and 10B or that are to be subsequently formed.

Subsequently, the processing steps described with reference to FIGS. 10A and 10B may be repeated as many times as needed to form all of the first vertical steps VS1. The first trimmable photoresist layer 677 may be removed thereafter, for example, by ashing.

Referring to FIGS. 11A and 11B, a second trimmable photoresist layer 679 can be applied over the hard mask layer 26, and can be lithographically patterned to form an initial slit-shaped opening. The second trimmable photoresist layer 679 includes a trimmable photoresist material. According to an aspect of the present disclosure, the two edges of the initial slit-shaped openings may coincide with the locations of a pair of second vertical steps VS2 to be subsequently formed in a plan view such as a top-down view. Unmasked portions of the alternating stack (32, 42) may be etched by a pair a sacrificial material layer 42 and an insulating layer 32 by performing an anisotropic etch process. After the processing steps of FIGS. 11A and 11B, two second vertical steps VS2 can be patterned in the alternating stack (32, 42). FIG. 11B illustrate the locations of all first vertical steps VS1 and all second vertical steps VS2 that are present upon completion of the processing steps of FIGS. 11A and 11B or that are to be subsequently formed.

Referring to FIGS. 12A and 12B, the second trimmable photoresist layer 679 can be trimmed (i.e., slimmed) by performing a controlled ashing process. The lateral trimming distance can be selected such that the straight edges of the second trimmable photoresist layer 679 after the trimming process are formed at locations of two second vertical steps VS2, which are neighboring second vertical steps VS2 with respective to the two vertical steps VS2 that are formed at the processing steps of FIGS. 11A and 11B. Unmasked portions of the alternating stack (32, 42) may be etched by a pair a sacrificial material layer 42 and an insulating layer 32 by performing an anisotropic etch process. After the processing steps of FIGS. 12A and 12B, four second vertical steps VS2 can be patterned in the alternating stack (32, 42). FIG. 12B illustrate the locations of all second vertical steps VS2 and all second vertical steps VS2 that are present upon completion of the processing steps of FIGS. 12A and 12B or that are to be subsequently formed.

Subsequently, the processing steps described with reference to FIGS. 12A and 12B may be repeated as many times as needed to form all of the second vertical steps VS2. The second trimmable photoresist layer 679 may be removed thereafter, for example, by ashing.

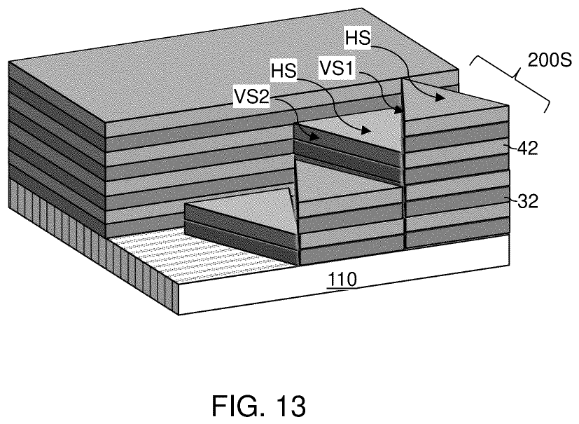

FIG. 13 is a perspective view of a region of the staircase region 200S of an exemplary structure after formation of stepped surfaces according to either the first or the second embodiment of the present disclosure.

Referring collectively to FIGS. 3A-13 and according to various embodiments of the present disclosure, the exemplary structure may comprise an alternating stack (32, 42) of insulating layers 32 and sacrificial material layers 42. The alternating stack (32, 42) has stepped surfaces in a staircase region 200S in which lateral extents of the sacrificial material layers 42 decrease with a vertical distance from a horizontal plane including a bottommost surface of the alternating stack (32, 42). The stepped surfaces in the staircase region comprise first vertical steps VS1 laterally extending along a first lateral direction ld1 which is at an acute angle a1 relative to the first horizontal direction hd1 in a plan view along a vertical direction. In one embodiment, the entirety of each first vertical step VS1 may be parallel to the first lateral direction ld1. The stepped surfaces in the staircase region also comprise second vertical steps VS2 laterally extending along a second lateral direction which is at an obtuse angle a2 relative to the first horizontal direction hd1 in the plan view along the vertical direction. In one embodiment, the entirety of each second vertical step VS2 may be parallel to the second lateral direction ld2.

In one embodiment, a subset of the second vertical steps VS2 is adjoined to a subset of the first vertical steps VS1. In one embodiment, each of the second vertical steps VS2 may be adjoined to a respective one of the first vertical steps VS1. In one embodiment, a subset of the first vertical steps VS1 is adjoined to the staircase-region sidewall SRS of a respective stepped cavity 69. In one embodiment, each of the first vertical steps VS1 is adjoined to the staircase-region sidewall SRS of a respective stepped cavity 69. In one embodiment, a subset of the second vertical steps VS2 is adjoined to the staircase-region sidewall SRS of a respective stepped cavity 69. In one embodiment, each of the second vertical steps VS2 is adjoined to the staircase-region sidewall SRS of a respective stepped cavity 69.

In one embodiment shown in FIG. 13, the stepped surfaces of each stepped cavity 69 comprise horizontal surface segments HS adjoined to the first vertical steps VS1 and the second vertical steps VS2 of the stepped surfaces. In one embodiment, one of the horizontal surface segments HS comprises a first edge that coincides with a top edge of one of the first vertical steps VS1 and a second edge that coincides with a bottom edge of one of the second vertical steps VS2. In one embodiment, a first subset of the horizontal surface segments HS comprises a respective first edge that coincides with a top edge of a respective first one of the first vertical steps VS1 and a respective second edge that coincides with a bottom edge of a respective second one of the second vertical steps VS2.

In one embodiment, another of the horizontal surface segments HS comprises an edge that coincides with a top edge of another of the first vertical steps VS1 and another edge that coincides with a bottom edge of yet another of the first vertical steps VS1. In one embodiment, a second subset of the horizontal surface segments HS comprises a respective first edge that coincides with a top edge of a respective first one of the first vertical steps VS1 and a respective second edge that coincides with a bottom edge of a respective second one of the first vertical steps VS1.

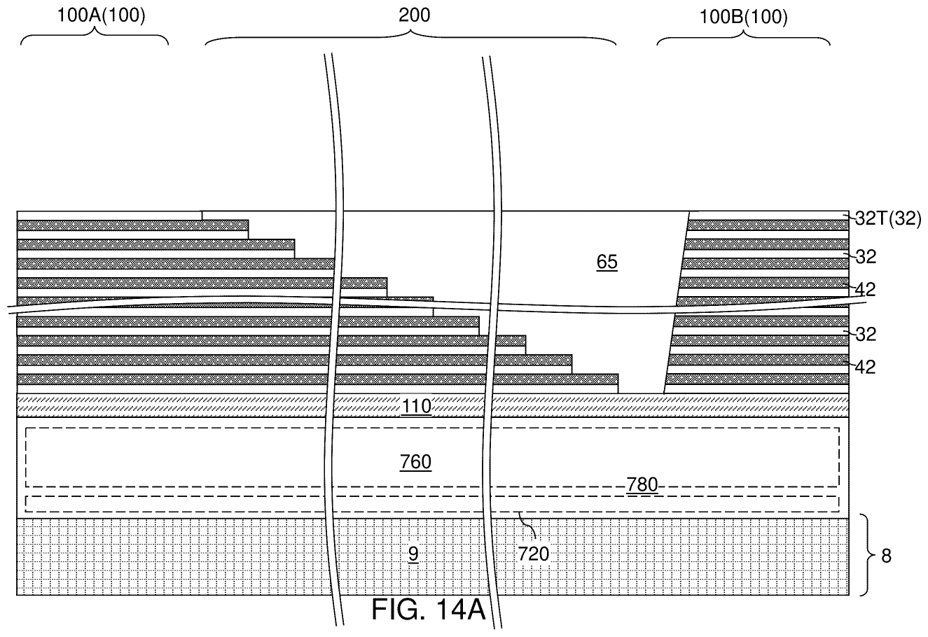

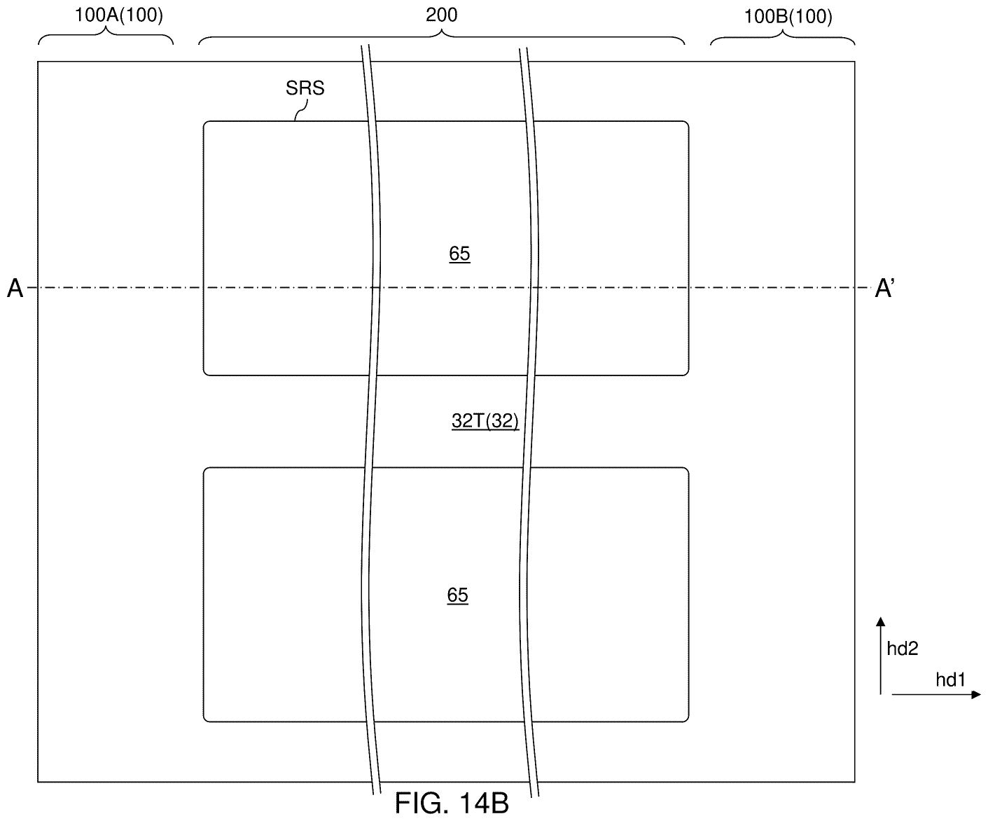

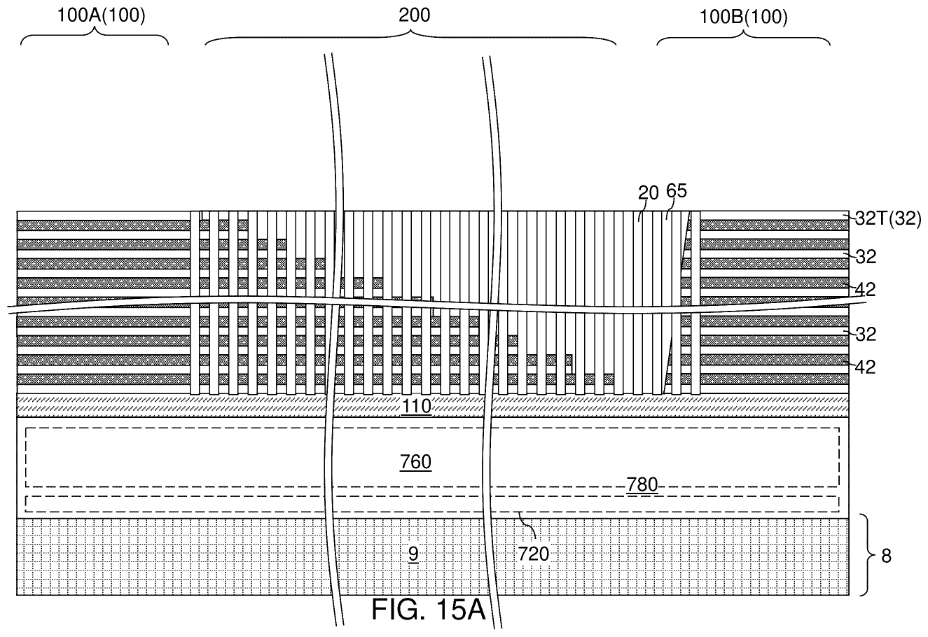

Referring to FIGS. 14A and 14B, a dielectric fill material (such as undoped silicate glass (i.e., silicon oxide) or a doped silicate glass) can be deposited in each stepped cavity. The dielectric fill material can be planarized to remove excess portions of the dielectric fill material from above the horizontal plane including the topmost surface of the alternating stack (32, 42). Each remaining portion of the dielectric fill material that fills a respective stepped cavity 69 constitutes a retro-stepped dielectric material portion 65. Each retro-stepped dielectric material portion 65 is formed over stepped surfaces of the alternating stack (32, 42).

Each retro-stepped dielectric material portions 65 fills a respective stepped cavity 69. Each retro-stepped dielectric material portion 65 has a first variable lateral extent along the first horizontal direction (e.g., word line direction) hd1 that decreases stepwise with a vertical distance from the horizontal plane including the bottommost surface of the alternating stack (32, 42). In one embodiment, the retro-stepped dielectric material portion 65 has a pair of tapered sidewalls that extend along the first horizontal direction hd1. Each retro-stepped dielectric material portion may have a pair of lengthwise sidewalls laterally extending along the first horizontal direction hd1 and having a respective stepped bottom edge that is adjoined to edges of underlying stepped surfaces of the stepped cavity 69.

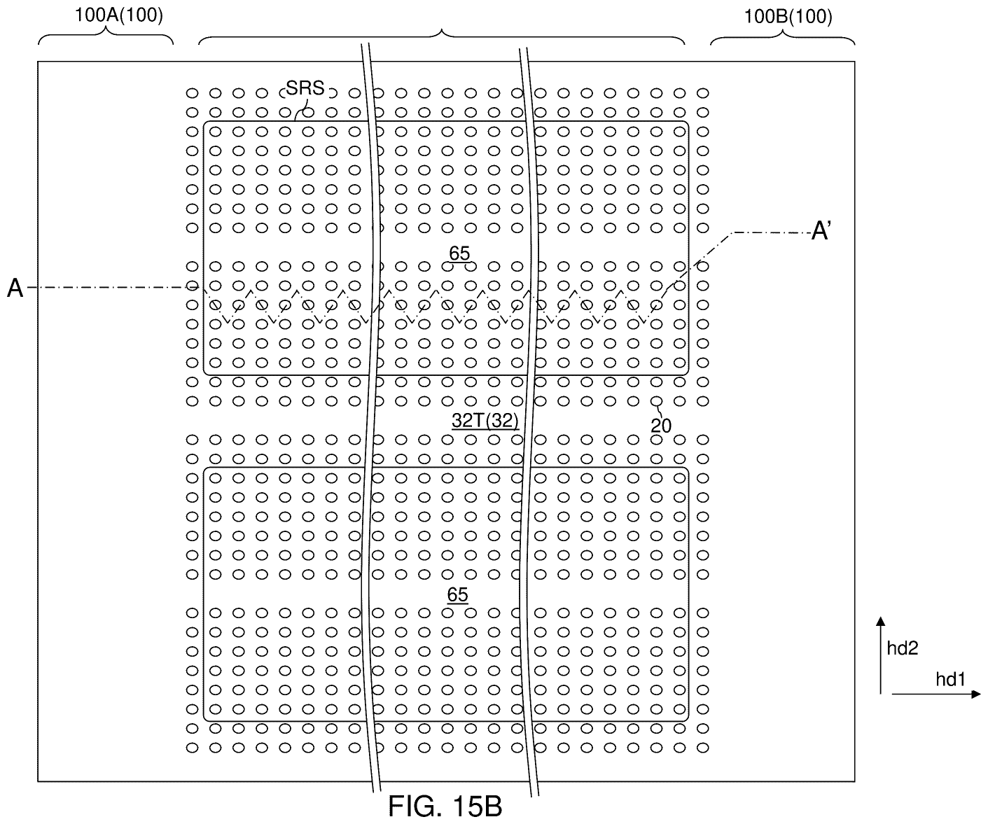

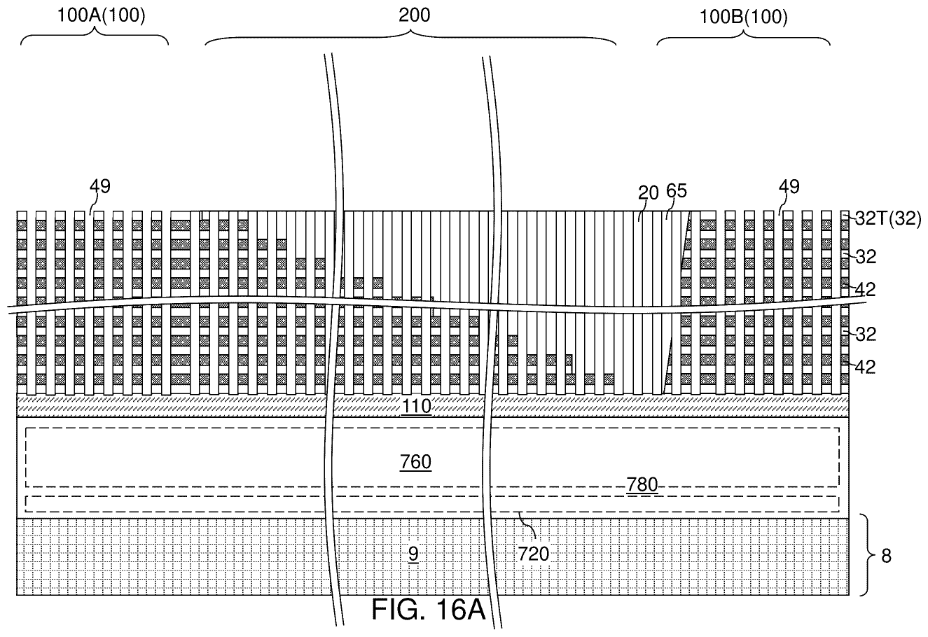

Referring to FIGS. 15A and 15B, an optional photoresist layer (not shown) can be applied over the alternating stack (32, 42) and the retro-stepped dielectric material portions 65, and can be lithographically patterned to form arrays of openings in the inter-array region 200. An anisotropic etch process can be performed to transfer the pattern of the opening in the photoresist layer through the retro-stepped dielectric material portions 65 and/or through the alternating stack (32, 42) to form optional support openings. Each of the support openings may vertically extend downward from the horizontal plane including the topmost surface of the alternating stack (32, 42) at least to the horizontal plane including the bottommost surface of the alternating stack (32, 42), and optionally into an upper portion of the semiconductor material layer 110. The photoresist layer can be subsequently removed, for example, by ashing.

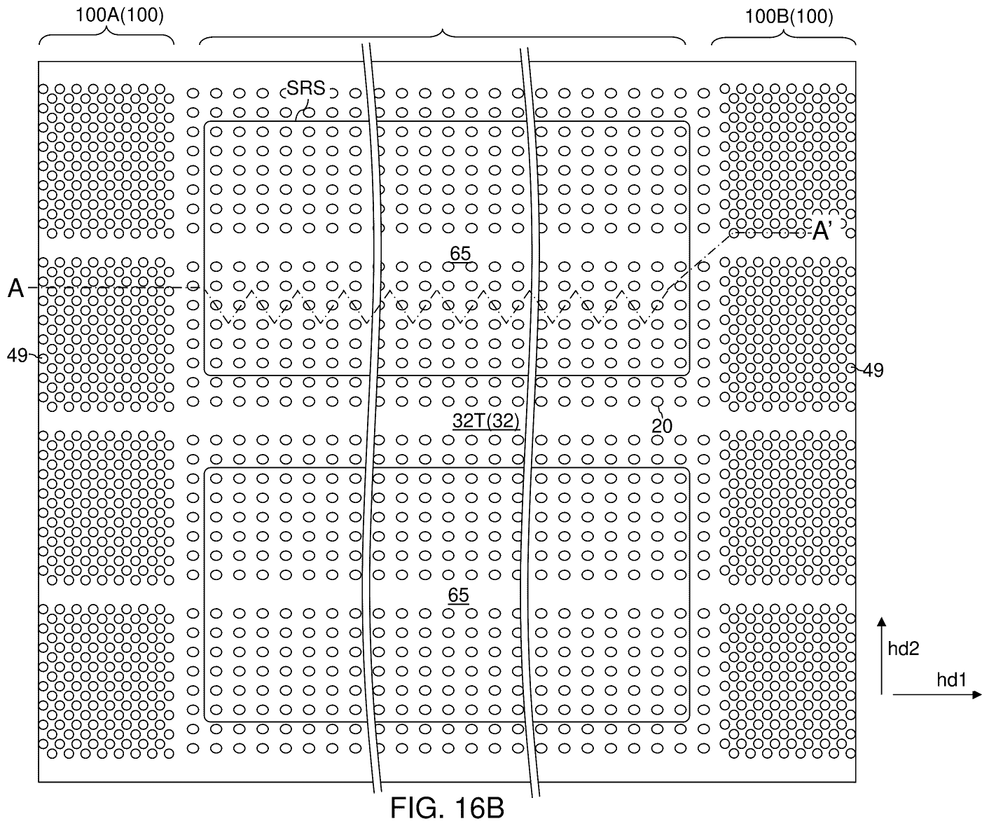

At least one dielectric fill material, such as undoped silicate glass (i.e., silicon oxide) and/or a doped silicate glass can optionally be deposited in the support openings. Excess portions of the at least one dielectric fill material can be removed from above the horizontal plane including the top surface of the topmost insulating layer 32T by a planarization process, which may employ a recess etch process. Remaining portions of the at least one dielectric fill material constitutes optional support pillar structures 20, which are subsequently used to provide structural support during replacement of the sacrificial material layers 42 with electrically conductive layers. Alternatively, the step illustrated in FIGS. 5A and 5B may be omitted, and the support pillar structures 20 may be formed during the same processing steps as the memory opening fill structures, as will be described below with respect to FIGS. 16A to 18B.

Referring to FIGS. 16A and 16B, a photoresist layer (not shown) can be applied over the alternating stack (32, 42), and can be lithographically patterned to form arrays of memory openings 49 in the memory regions 100. An anisotropic etch process can be performed to transfer the pattern of the opening in the photoresist layer through the alternating stack (32, 42) to form memory openings 49. Each of the memory openings 49 may vertically extend downward from the horizontal plane including the topmost surface of the alternating stack (32, 42) at least to the horizontal plane including the bottommost surface of the alternating stack (32, 42), and optionally into an upper portion of the semiconductor material layer 110. The photoresist layer can be subsequently removed, for example, by ashing. In the alternative embodiment, the above described support openings in the inter-array region 200 may be formed at the same time as the memory openings 49 in the memory regions 100.

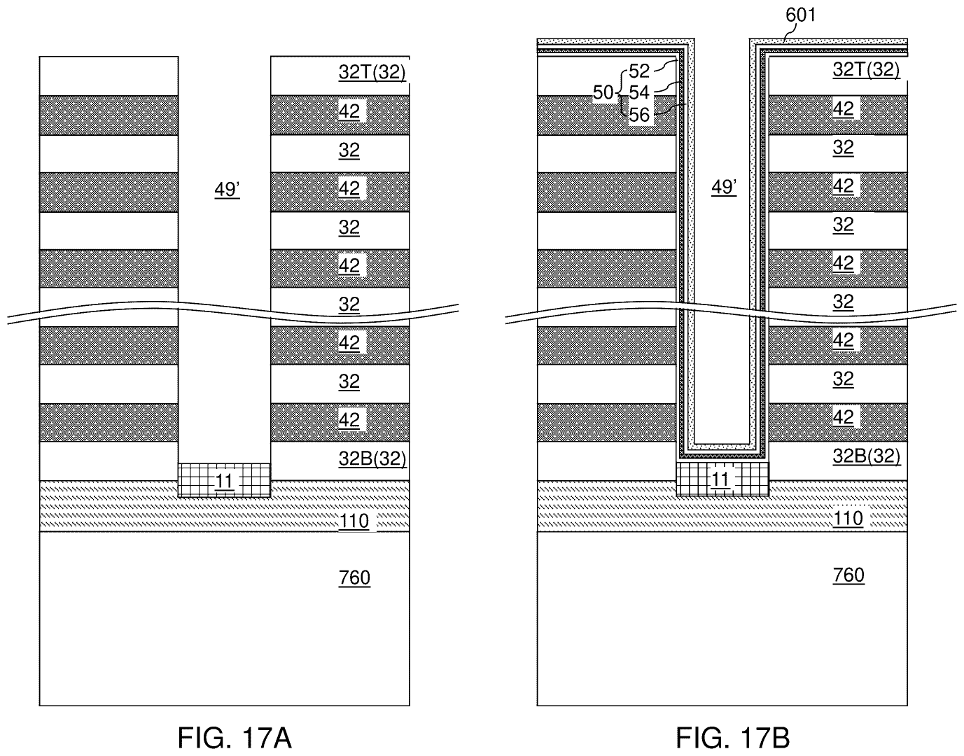

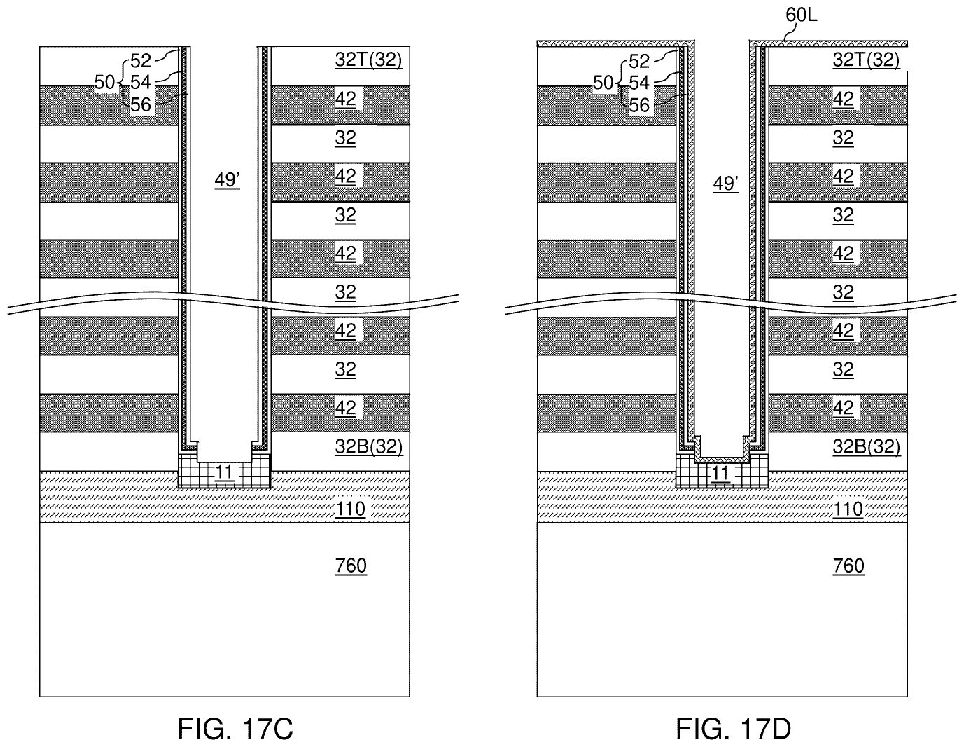

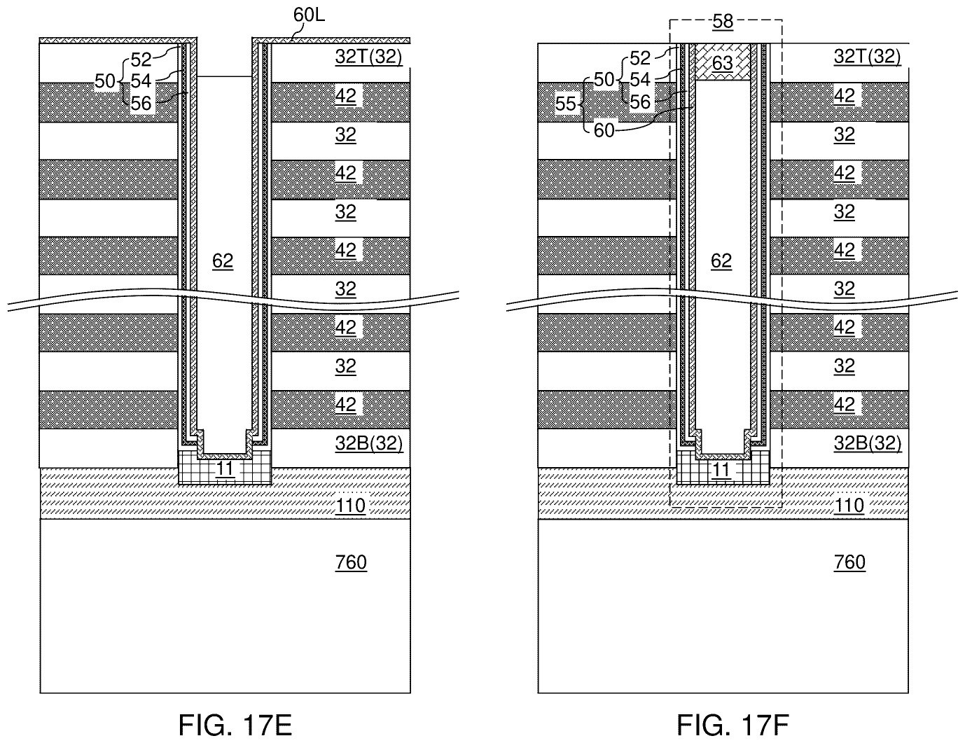

FIGS. 17A-17F are sequential vertical cross-sectional views of a region around a memory opening during formation of a memory opening fill structure according to an embodiment of the present disclosure.

Referring to FIG. 17A, a memory opening 49 in the exemplary device structure of FIGS. 16A and 16B is illustrated. The memory opening 49 extends through the alternating stack (32, 42), and optionally into an upper portion of the semiconductor material layer 110. The recess depth of the bottom surface of each memory opening 49 with respect to the top surface of the semiconductor material layer 110 can be in a range from 0 nm to 30 nm, although greater recess depths can also be employed. Optionally, the sacrificial material layers 42 can be laterally recessed partially to form laterally-extending cavities (not shown), for example, by an isotropic etch.

An optional pedestal channel portion 11 (which may be a silicon pedestal) can be formed at the bottom portion of each memory opening 49, for example, by a selective semiconductor deposition process. In one embodiment, the pedestal channel portion 11 can be doped with electrical dopants of the same conductivity type as the semiconductor material layer 110, which is a first conductivity type. In one embodiment, the top surface of each pedestal channel portion 11 can be formed below a horizontal plane including the top surface of the bottommost insulating layer 32B. The pedestal channel portion 11 can be a portion of a transistor channel that extends between a source region to be subsequently formed in the semiconductor material layer 110 and a drain region to be subsequently formed in an upper portion of the memory opening 49. A memory cavity 49′ is present in the unfilled portion of the memory opening 49 above the pedestal channel portion 11.

Referring to FIG. 17B, a stack of layers including a blocking dielectric layer 52, a memory material layer 54, and an optional dielectric liner 56 can be deposited in each memory opening 49. The stack of layers is herein referred to as a memory film 50.

The blocking dielectric layer 52 can include a single dielectric material layer or a stack of a plurality of dielectric material layers. In one embodiment, the blocking dielectric layer 52 can include a dielectric metal oxide layer consisting essentially of a dielectric metal oxide. In one embodiment, the blocking dielectric layer 52 can include a dielectric metal oxide having a dielectric constant greater than 7.9, i.e., having a dielectric constant greater than the dielectric constant of silicon nitride. Alternatively or additionally, the blocking dielectric layer 52 can include a dielectric semiconductor compound such as silicon oxide, silicon oxynitride, silicon nitride, or a combination thereof. In one embodiment, the blocking dielectric layer 52 can include silicon oxide. In this case, the dielectric semiconductor compound of the blocking dielectric layer 52 can be formed by a conformal deposition method such as low pressure chemical vapor deposition, atomic layer deposition, or a combination thereof. The thickness of the dielectric semiconductor compound can be in a range from 1 nm to 20 nm, although lesser and greater thicknesses can also be employed.

The memory material layer 54 may comprise any memory material such as a charge storage material, a ferroelectric material, a phase change material, or any material that can store data bits in the form of presence or absence of electrical charges, a direction of ferroelectric polarization, electrical resistivity, or another measurable physical parameter. In one embodiment, the memory material layer 54 can be a continuous layer or patterned discrete portions of a charge trapping material including a dielectric charge trapping material, which can be, for example, silicon nitride. Alternatively, the memory material layer 54 can include a continuous layer or patterned discrete portions of a conductive material such as doped polysilicon or a metallic material that is patterned into multiple electrically isolated portions (e.g., floating gates), for example, by being formed within laterally-extending cavities into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single continuous layer. Generally, the memory material layer 54 may comprise a vertical stack of memory elements that are located at levels of the sacrificial material layers 42. For example, the vertical stack of memory elements may be embodied as annular portions of the memory material layer 54 located at levels of the sacrificial material layers 42.

The optional dielectric liner 56, if present, comprises a dielectric liner material. In one embodiment, the dielectric liner 56 may comprise a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof.

In one embodiment, the dielectric liner 56 can include a stack of a first silicon oxide layer, a silicon oxynitride layer, and a second silicon oxide layer, which is commonly known as an ONO stack. In one embodiment, the dielectric liner 56 can include a silicon oxide layer that is substantially free of carbon or a silicon oxynitride layer that is substantially free of carbon. The thickness of the dielectric liner 56 can be in a range from 2 nm to 20 nm, although lesser and greater thicknesses can also be employed. Optionally, a sacrificial cover material layer 601 may be formed over the memory film 50.

Referring to FIG. 17C, the optional sacrificial cover material layer 601, the dielectric liner 56, the memory material layer 54, the blocking dielectric layer 52 are sequentially anisotropically etched employing at least one anisotropic etch process. The portions of the sacrificial cover material layer 601, the dielectric liner 56, the memory material layer 54, and the blocking dielectric layer 52 located above the top surface of the topmost insulating layer 32T can be removed by the at least one anisotropic etch process. Further, the horizontal portions of the sacrificial cover material layer 601, the dielectric liner 56, the memory material layer 54, and the blocking dielectric layer 52 at a bottom of each memory cavity 49′ can be removed to form openings in remaining portions thereof. Each of the sacrificial cover material layer, the dielectric liner 56, the memory material layer 54, and the blocking dielectric layer 52 can be etched by a respective anisotropic etch process employing a respective etch chemistry, which may or may not be the same for the various material layers.

Each remaining portion of the sacrificial cover material layer 601, if employed, can have a tubular configuration. A surface of the pedestal channel portion 11 (or a surface of the semiconductor material layer 110 in case a pedestal channel portions 11 is not employed) can be physically exposed underneath the opening through the sacrificial cover material layer, the dielectric liner 56, the memory material layer 54, and the dielectric metal oxide blocking dielectric layer 52. Optionally, the physically exposed semiconductor surface at the bottom of each memory cavity 49′ can be vertically recessed so that the recessed semiconductor surface underneath the memory cavity 49′ is vertically offset from the topmost surface of the pedestal channel portion 11 (or of the semiconductor material layer 110 in case pedestal channel portions 11 are not employed) by a recess distance. In one embodiment, the sacrificial cover material layer 601, the dielectric liner 56, the memory material layer 54, and the blocking dielectric layer 52 can have vertically coincident sidewalls. The sacrificial cover material layer 601 can be subsequently removed selective to the material of the dielectric liner 56. In case the sacrificial cover material layer 601 includes amorphous silicon, a wet etch process employing hot trimethyl-2 hydroxyethyl ammonium hydroxide (“hot TMY”) or tetramethyl ammonium hydroxide (TMAH) can be performed to remove the sacrificial cover material layer. Alternatively, the sacrificial cover material layer 601 may be retained in the final device if it comprises a silicon material.

Referring to FIG. 17D, a semiconductor channel layer 60L can be deposited directly on the semiconductor surface of the pedestal channel portion 11 or the semiconductor material layer 110 if the pedestal channel portion 11 is omitted, and directly on the memory film 50. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can have a doping of a first conductivity type, which is the same as the conductivity type of the semiconductor material layer 110 and the pedestal channel portions 11. The semiconductor channel layer 60L can be formed by a conformal deposition method such as low pressure chemical vapor deposition (LPCVD). The thickness of the semiconductor channel layer 60L can be in a range from 2 nm to 10 nm, although lesser and greater thicknesses can also be employed. The semiconductor channel layer 60L may partially fill the memory cavity 49′ in each memory opening, or may fully fill the cavity in each memory opening.

Referring to FIG. 17E, a dielectric core layer can be deposited to fill any remaining portion of the memory cavity 49′ within each memory opening 49. The dielectric core layer includes a dielectric material such as silicon oxide or organosilicate glass. The dielectric core layer can be deposited by a conformal deposition method such as low pressure chemical vapor deposition (LPCVD), or by a self-planarizing deposition process such as spin coating.

The horizontal portion of the dielectric core layer can be removed, for example, by a recess etch process such that each remaining portions of the dielectric core layer is located within a respective memory opening 49 and has a respective top surface below the horizontal plane including the top surface of the topmost insulating layer 32T. Each remaining portion of the dielectric core layer constitutes a dielectric core 62.

Referring to FIG. 17F, a doped semiconductor material having a doping of a second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each combination of a memory film 50 and a vertical semiconductor channel 60 within a memory opening 49 constitutes a memory stack structure 55. The memory stack structure 55 is a combination of a vertical semiconductor channel 60, an optional dielectric liner 56, a plurality of memory elements comprising portions of the memory material layer 54, and an optional blocking dielectric layer 52. Each combination of a pedestal channel portion 11 (if present), a memory stack structure 55, a dielectric core 62, and a drain region 63 within a memory opening 49 is herein referred to as a memory opening fill structure 58.

In the alternative embodiment in which the support openings are formed at the same time as the memory openings 49, the support pillar structures 20 may be formed in the support openings at the same time as the memory opening fill structures 58. In this alternative embodiment, the support pillar structures 20 have the same composition as the memory opening fill structures 58, but are not electrically connected to the subsequently formed bit lines.

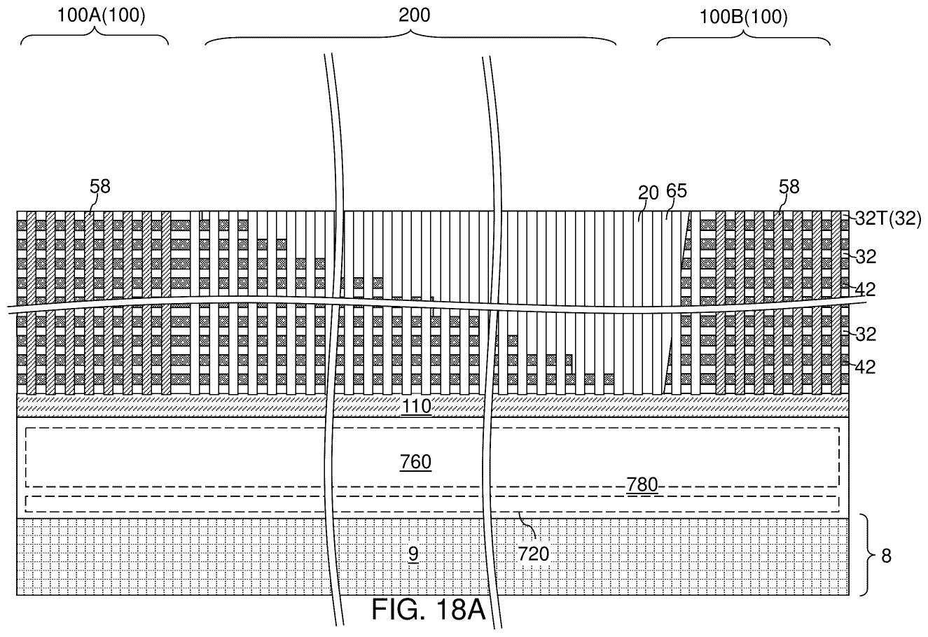

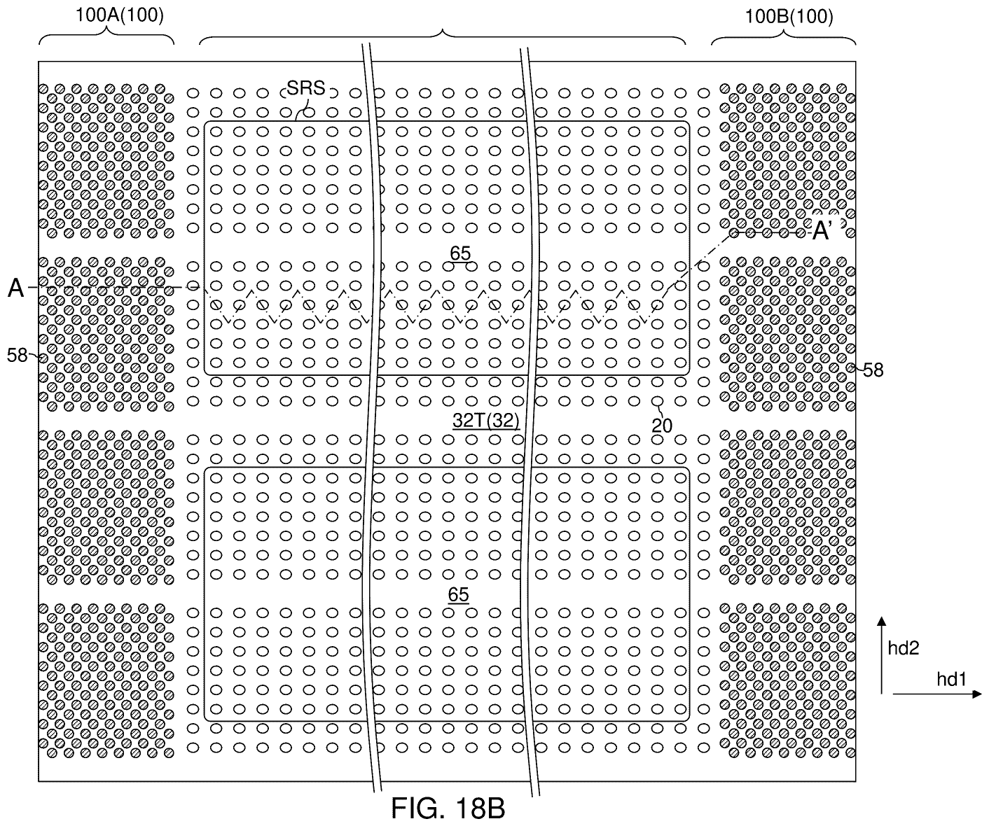

Referring to FIGS. 18A and 18B, the exemplary structure is illustrated after formation of memory opening fill structures 58 and support pillar structure 20 within the memory openings 49 and the support openings 19, respectively. An instance of a memory opening fill structure 58 can be formed within each memory opening 49. An instance of the support pillar structure 20 can be formed within each support opening. Other memory stack structures including different layer stacks or structures for the memory film 50 and/or for the vertical semiconductor channel 60 may also be used.

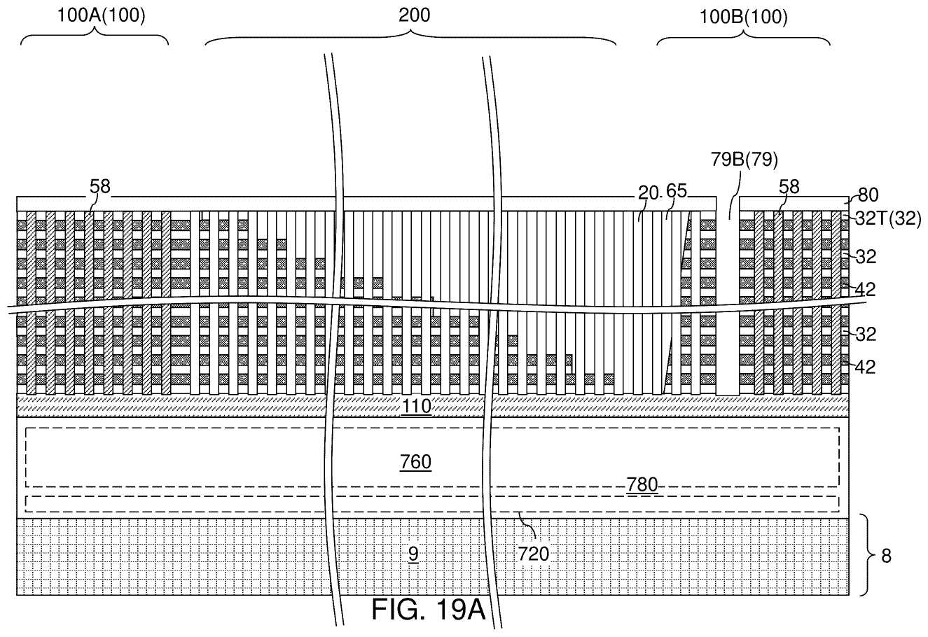

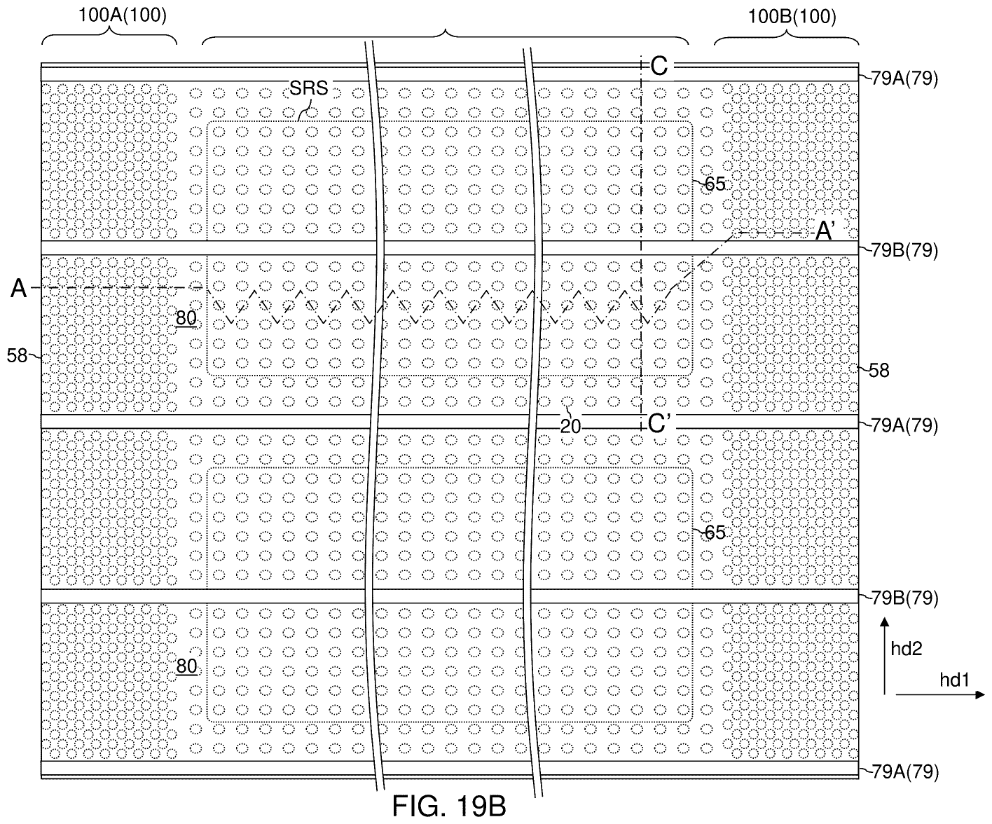

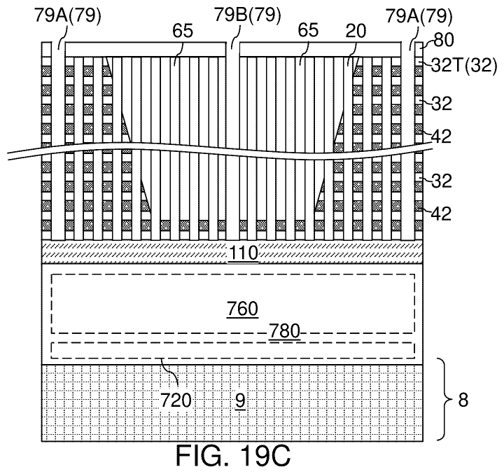

Referring to FIGS. 19A-19C, a contact-level dielectric layer 80 can be formed over the alternating stack (32, 42) of insulating layer 32 and sacrificial material layers 42, and over the memory opening fill structures 58 and the support pillar structures 20. The contact-level dielectric layer 80 includes a dielectric material that is different from the dielectric material of the sacrificial material layers 42. For example, the contact-level dielectric layer 80 can include silicon oxide. The contact-level dielectric layer 80 can have a thickness in a range from 50 nm to 500 nm, although lesser and greater thicknesses can also be employed.

A photoresist layer (not shown) can be applied over the contact-level dielectric layer 80, and is lithographically patterned to form elongated openings in areas between clusters of memory opening fill structures 58. The pattern in the photoresist layer can be transferred through the contact-level dielectric layer 80, the alternating stack (32, 42), and the retro-stepped dielectric material portions 65 employing an anisotropic etch to form lateral isolation trenches 79, which vertically extend from the top surface of the contact-level dielectric layer 80 at least to the top surface of semiconductor material layer 110, and laterally extend through at least one memory array region 100 and at least a peripheral portion the inter-array region 200.

In one embodiment, the lateral isolation trenches 79 can laterally extend along a first horizontal direction hd1 (which is a word line direction), and can be laterally spaced apart among one another along a second horizontal direction hd2 (which is a bit line direction) that is perpendicular to the first horizontal direction hd1. The memory opening fill structures 58 can be arranged in rows that extend along the first horizontal direction hd1. Each lateral isolation trench 79 can have a uniform width that is invariant along the lengthwise direction (i.e., along the first horizontal direction hd1). Multiple rows of memory opening fill structures can be located between a neighboring pair of lateral isolation trenches 79. In one embodiment, the lateral isolation trenches 79 can include source contact openings in which source contact via structures can be subsequently formed. The photoresist layer can be removed, for example, by ashing.

In one embodiment, the lateral isolation trenches 79 comprise first-type lateral isolation trenches 79A and second-type lateral isolation trenches 79B that are interlaced with the first-type lateral isolation trenches 79A along the second horizontal direction hd2. Each of the first-type lateral isolation trenches 79A laterally extends continuously through the inter-array region 200, the first memory array region 100A, and the second memory array region 100B along the first horizontal direction hd1 between a respective neighboring pair of retro-stepped dielectric material portions 65. Thus, the first-type lateral isolation trenches 79A do not cut through any of the retro-stepped dielectric material portions 65 or through the staircase regions 200S. Each of the second-type lateral isolation trenches 79B laterally extends continuously through the inter-array region 200, the first memory array region 100A, and the second memory array region 100B along the first horizontal direction hd1, and bisects a respective one of the retro-stepped dielectric material portions 65 and a respective one of the staircase regions 200S.

In summary, lateral isolation trenches 79 laterally extending along the first horizontal direction hd1 can be formed through the contact-level dielectric layer 80 and the alternating stack (32, 42). The alternating stack (32, 42) is divided into multiple alternating stacks (32, 42) that are laterally spaced apart along the second horizontal direction hd2 by the lateral isolation trenches 79. Layer stacks (32, 42, 80) are formed, each of which includes a respective patterned portion of the contact-level dielectric layer 80 and a respective alternating stack (32, 42) and laterally spaced from each other by the lateral isolation trenches 79.

The first-type lateral isolation trenches 79A may be laterally interlaced with the retro-stepped dielectric material portions 65 along the second horizontal direction hd2. The width of the lateral isolation trenches 79 can be greater than the thickness of each sacrificial material layer 42. For example, the ratio of the width of the lateral isolation trenches 79 along the second horizontal direction hd2 to the thickness of each sacrificial material layer 42 may be in a range from 2 to 30, such as from 4 to 15, although lesser and greater ratios may also be employed.

In one embodiment, a staircase-region sidewall SRS of each staircase region may be laterally offset from each of the plurality of lateral isolation trenches 79. In one embodiment, another staircase-region sidewall SRS of each staircase region may coincide with a lengthwise sidewall of a respective one of the lateral isolation trenches 79.

Each alternating stack (32, 42) has a respective pair of lengthwise sidewalls that laterally extend along the first horizontal direction hd1. A retro-stepped dielectric material portion 65 overlies the stepped surfaces of each alternating stack (32, 42) in the staircase region 200S. The retro-stepped dielectric material portion 65 has a width along a second horizontal direction hd2 that is perpendicular to the first horizontal direction hd1 that is less than a lateral spacing between a pair of lengthwise sidewalls of the alternating stack (32, 42).

In one embodiment, the retro-stepped dielectric material portion 65 comprises a first lengthwise sidewall having a first stepped bottom edge that is adjoined to first edges of the stepped surfaces of the alternating stack (32, 42), and a second lengthwise sidewall having a second stepped bottom edge that is adjoined to second edges of the stepped surfaces of the alternating stack (32, 42). As discussed above, the first lateral direction ld1 and the second lateral direction ld2 are not perpendicular to and are not parallel to the first horizontal direction hd1. Thus, the second stepped bottom edge is not congruent with the first stepped bottom edge for each retro-stepped dielectric material portion 65. Furthermore, the first lateral direction ld1 and the second lateral direction ld2 are not perpendicular to and are not parallel to the length direction hd1 of the lateral isolation trenches 79. The lateral directions hd1 and ld2 extend at angle of 30 to 80 degrees relative to the length direction hd1.

In one embodiment, each of the first vertical steps VS1 and the second vertical steps VS2 has a respective lateral extent along a second horizontal direction hd2 that is perpendicular to the first horizontal direction hd1 that is less than a lateral spacing between the pair of lengthwise sidewalls. In one embodiment, the stepped surfaces comprise horizontal surface segments HS connecting a respective pair of vertical steps of the first vertical steps VS1 and the second vertical steps VS2 of the stepped surfaces. In one embodiment, a first subset of the horizontal surface segments has a respective lateral extent along the second horizontal direction hd2 that equals the width of the retro-stepped dielectric material portion 65 along the second horizontal direction hd2. In one embodiment, a second subset of the horizontal surface segments has a respective lateral extent along the second horizontal direction hd2 that is less than the width of the retro-stepped dielectric material portion 65 along the second horizontal direction hd2.

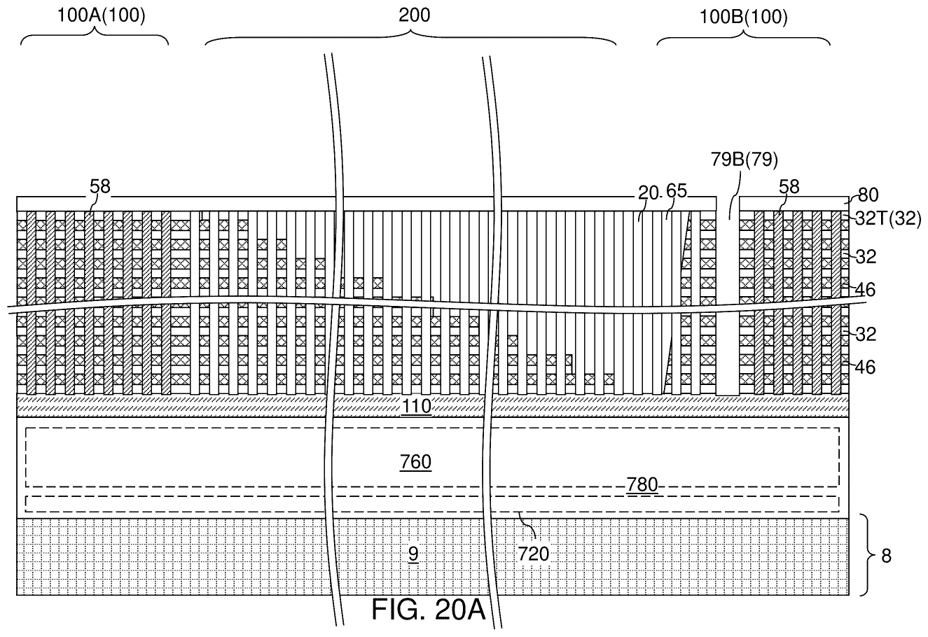

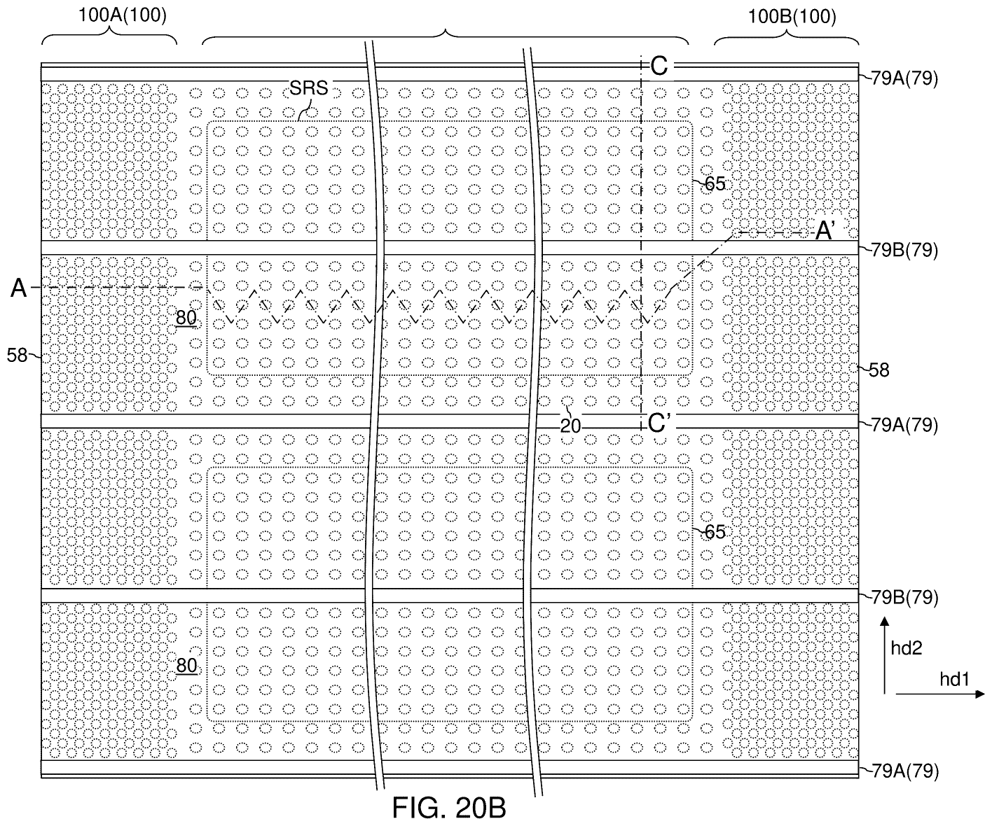

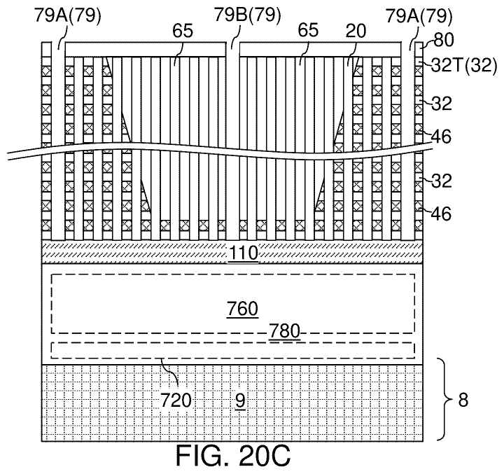

Referring to FIGS. 20A-20C, an isotropic etch process can be performed to introduce an isotropic etchant that etches a material of the sacrificial material layers 42 into the lateral isolation trenches 79. For example, if the sacrificial material layers 42 comprise silicon nitride, the isotropic etch process may comprise a wet etch process employing hot phosphoric acid. Laterally-extending cavities 43 are formed in volumes from which portions of the sacrificial material layers 42 are removed by the isotropic etch process. The isotropic etch process has an etch distance that is greater than one half of a lateral distance between the lateral spacing between neighboring pairs of lateral isolation trenches 79.

A backside blocking dielectric layer (not illustrated) may be optionally deposited in the laterally-extending cavities 43 on the physically exposed surfaces of the retro-stepped dielectric material portions 65, the memory opening fill structures 58, the support pillar structures 20, and the insulating layers 32 by a conformal deposition process. The backside blocking dielectric layer comprises a dielectric material such as a dielectric metal oxide (such as an aluminum oxide) and/or silicon oxide. The thickness of the backside blocking dielectric layer 44 may be in a range from 3 nm to 12 nm, although lesser and greater thicknesses may also be employed.

At least one conductive material can be deposited in unfilled volumes of the laterally-extending cavities 43 by providing at least one reactant gas into the laterally-extending cavities 43 through the lateral isolation trenches 79. For example, the at least one conductive material may comprise a metallic barrier layer and a metallic fill material. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

The metal fill material can be deposited over the metallic barrier layer to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas, such as WF₆. In one embodiment, the metallic fill material layer can be a tungsten layer including a residual level of fluorine atoms as impurities. The metallic fill material layer is spaced from the insulating layers 32 and the memory opening fill structures 58 by the metallic barrier layer, which is a metallic barrier layer that blocks diffusion of fluorine atoms therethrough.

A plurality of electrically conductive layers 46 can be formed in the plurality of laterally-extending cavities 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an etch process that etches the at least one conductive material of the continuous electrically conductive material layer. Each remaining portion of the deposited metallic material in the laterally-extending cavities 43 constitutes an electrically conductive layer 46. Each electrically conductive layer 46 can be a conductive line structure. Thus, the sacrificial material layers 42 are replaced with the electrically conductive layers 46.

The middle electrically conductive layers 46 can function as a combination of a plurality of control gate electrodes located at a same level and a word line electrically interconnecting, i.e., electrically shorting, the plurality of control gate electrodes located at the same level. The plurality of control gate electrodes within each electrically conductive layer 46 are the control gate electrodes for the vertical memory devices including the memory stack structures 55. In other words, the electrically conductive layer 46 can be a word line that functions as a common control gate electrode for the plurality of vertical memory devices. At least one upper most electrically conductive layer 46 may comprise a drain side select gate electrode. At least one lower most electrically conductive layer 46 may comprise a source side select gate electrode.

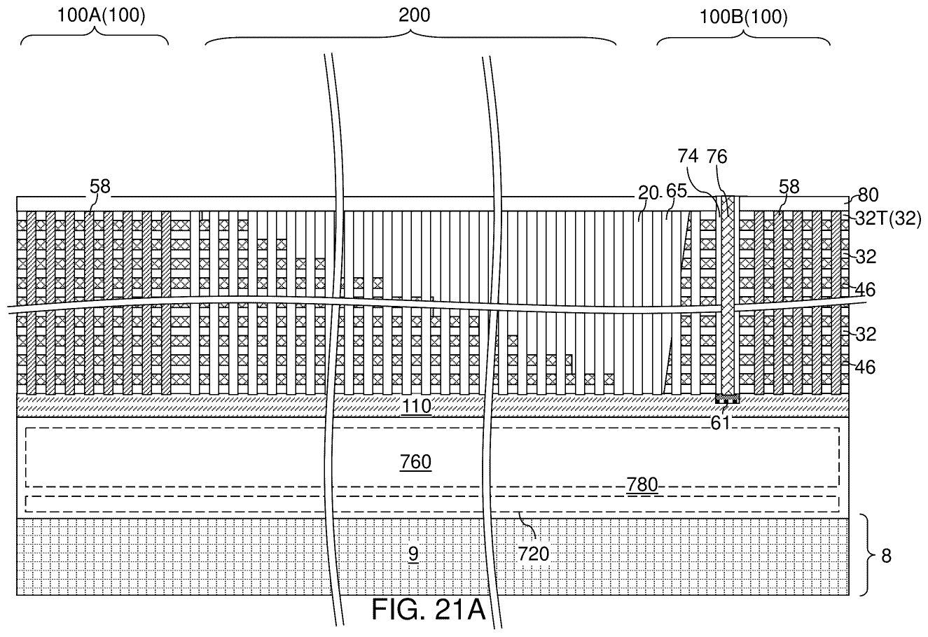

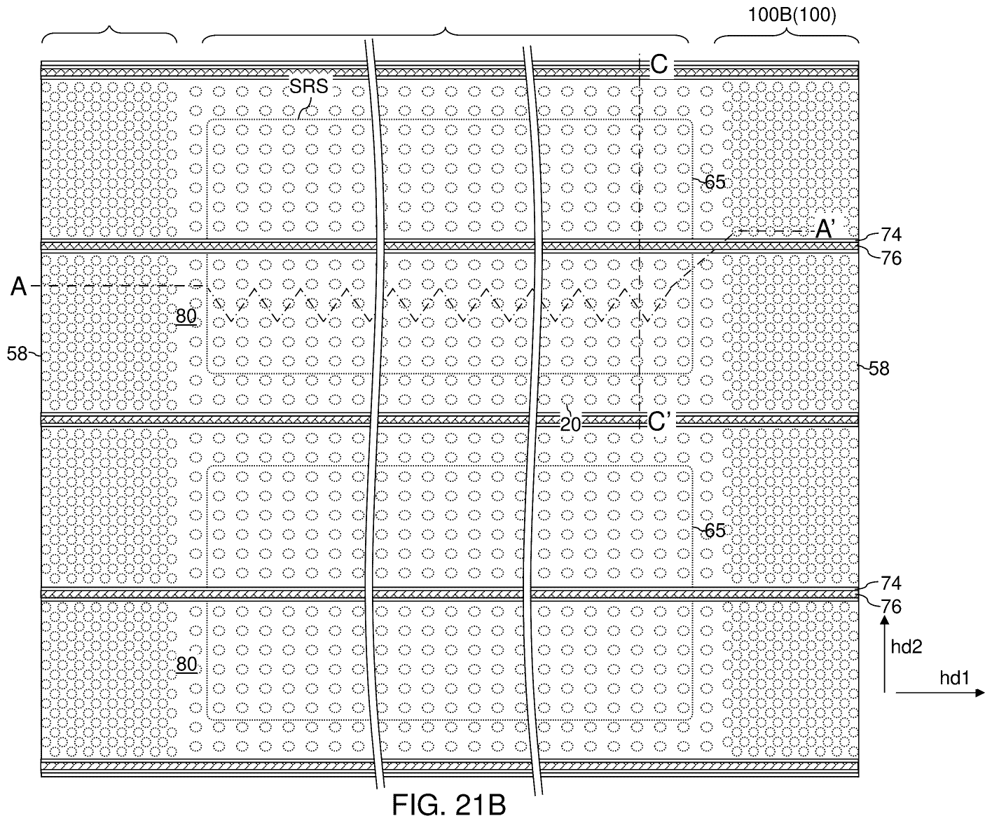

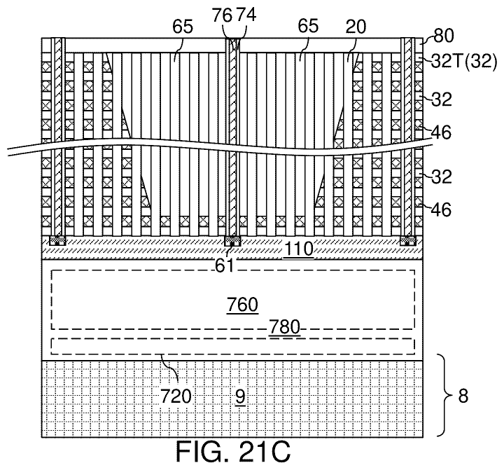

Referring to FIGS. 21A-21C, an ion implantation process can be optionally performed to implant dopants of the second conductivity type into surface portions of the semiconductor material layer 110 that underlie the lateral isolation trenches 79 to form optional source regions 61. An insulating material layer can be conformally deposited in the lateral isolation trenches 79 and the contact-level dielectric layer 80. An anisotropic etch process can be performed to remove horizontally-extending portions of the insulating material layer. Each remaining vertically-extending portion of the insulating material layer constitutes an insulating spacer 74.

At least one conducive material can be deposited in remaining unfilled volumes of the lateral isolation trenches 79 to form conductive wall structures 76. The at least one conductive material may comprise a metallic material and/or a heavily-doped semiconductor material. Each contiguous combination of an insulating spacer 74 and a conductive wall structure 76 constitutes a lateral isolation trench fill structure (74, 76) that fills a respective lateral isolation trench 79. Alternatively, the entirety of each lateral isolation trench may be filled with at least one insulating material. In this case, the lateral isolation trench fill structures may consist essentially of at least one insulating material.

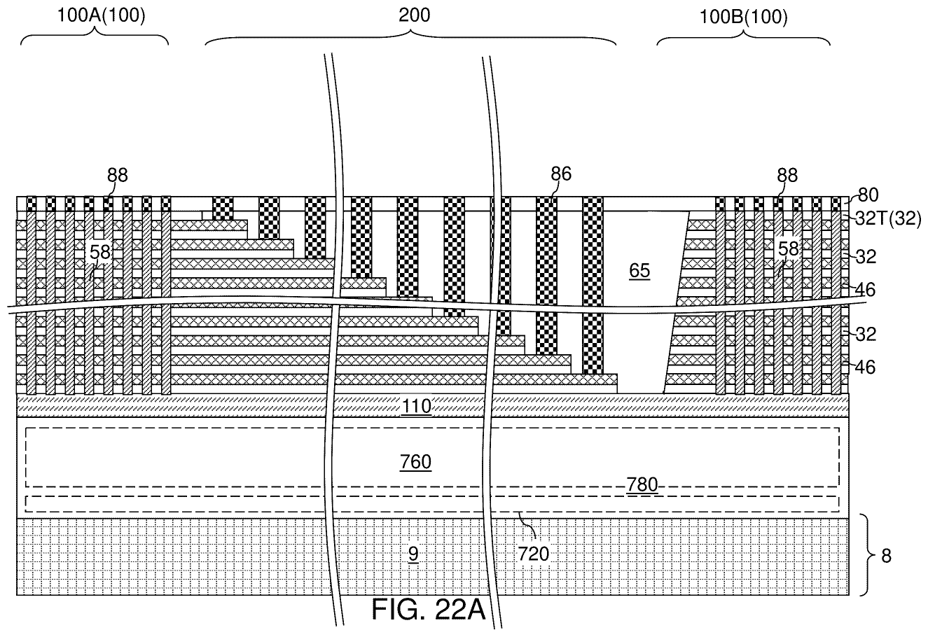

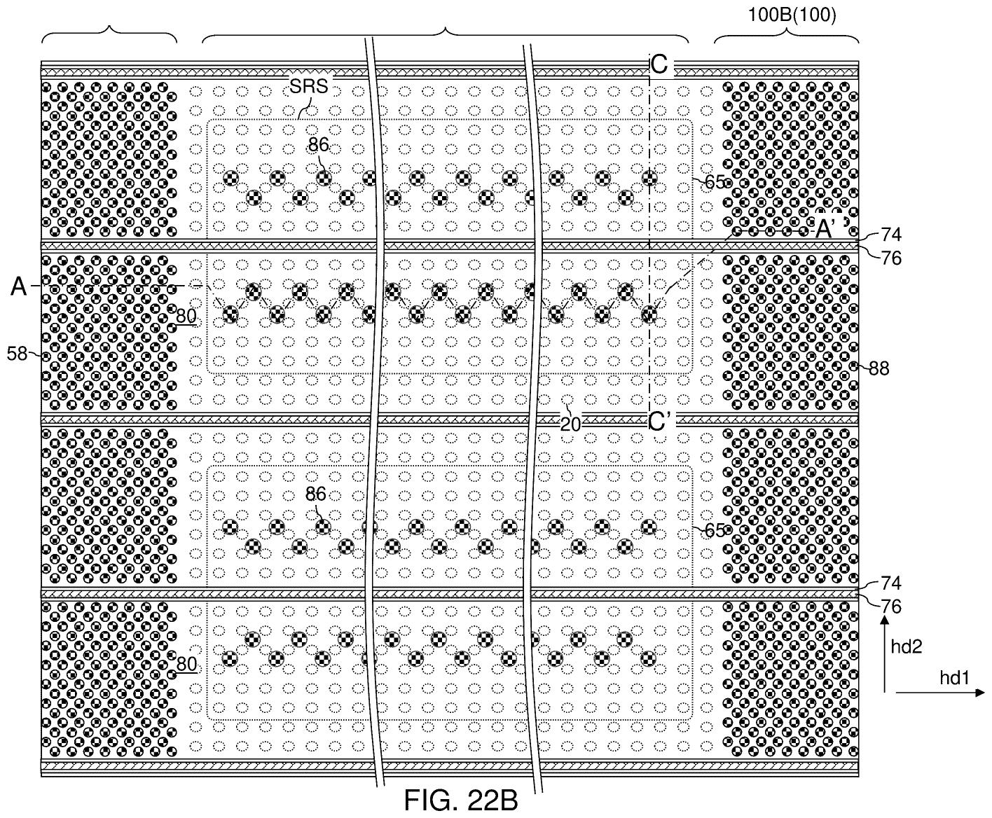

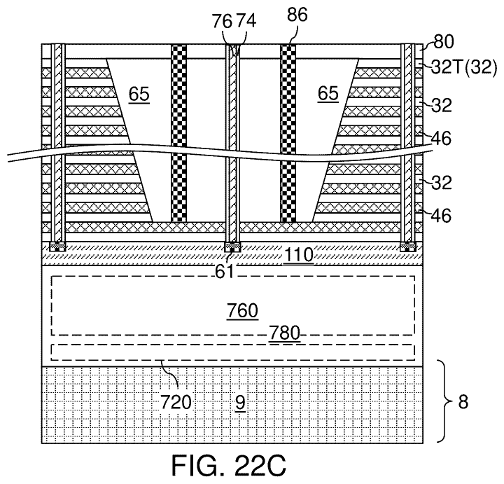

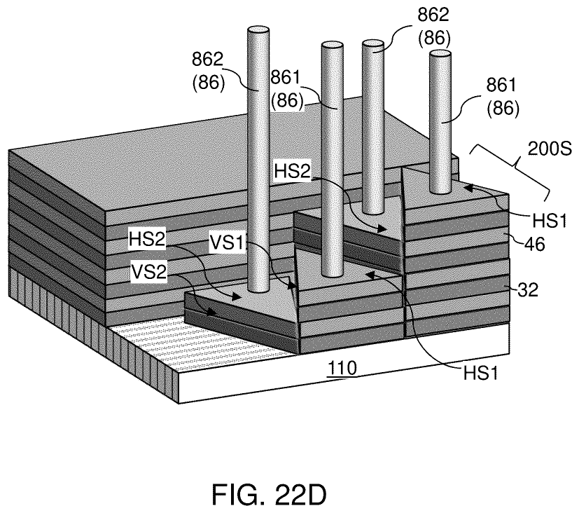

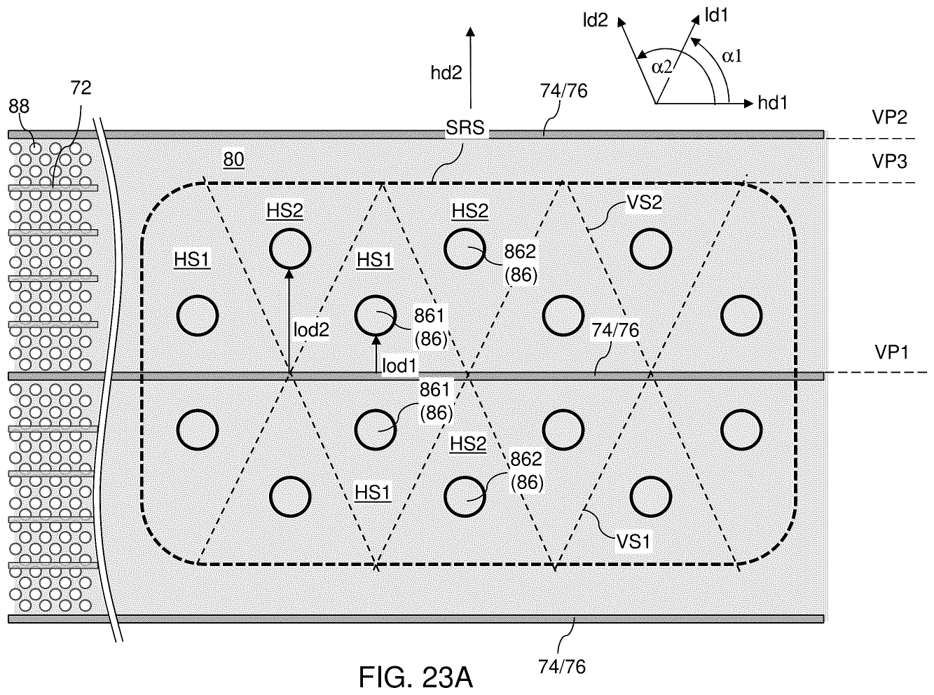

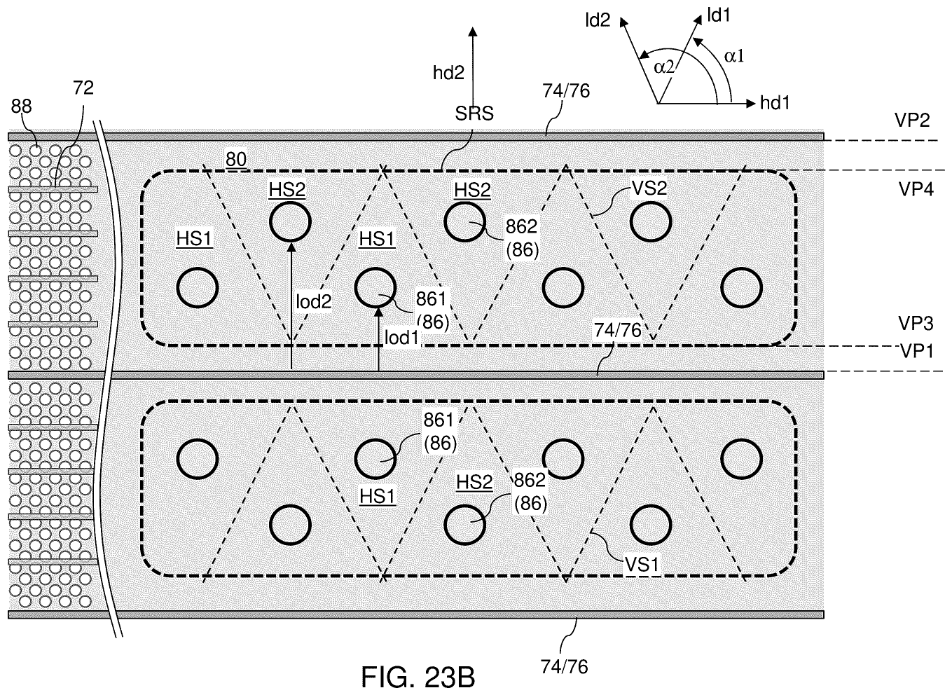

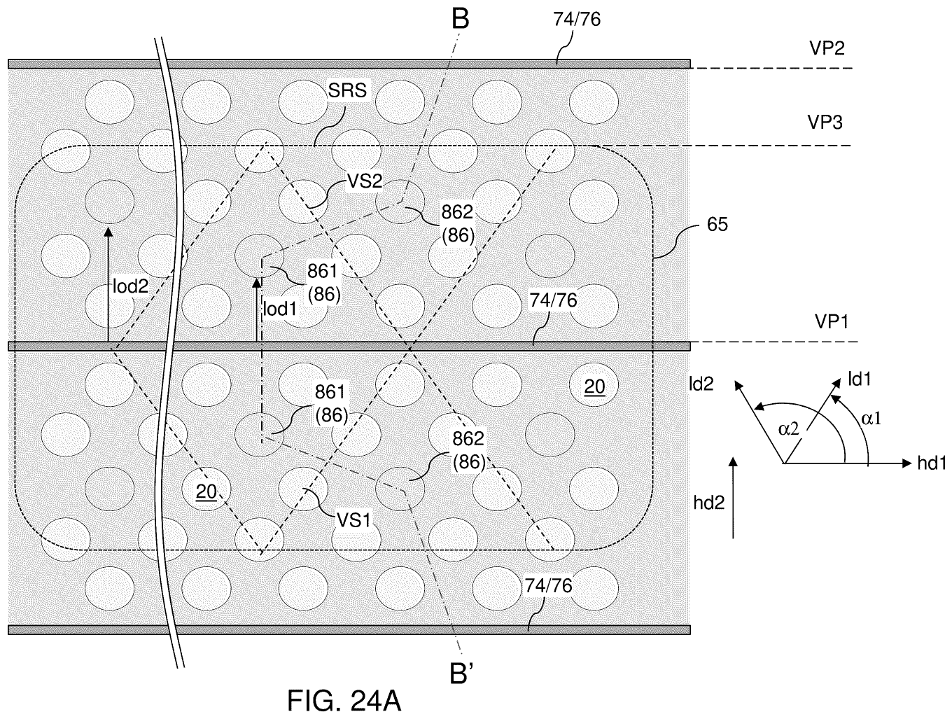

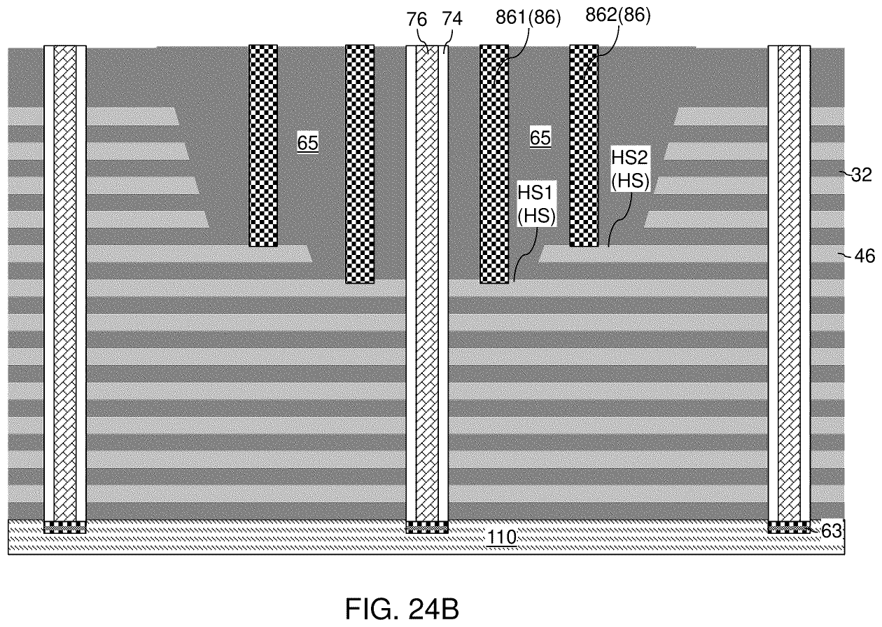

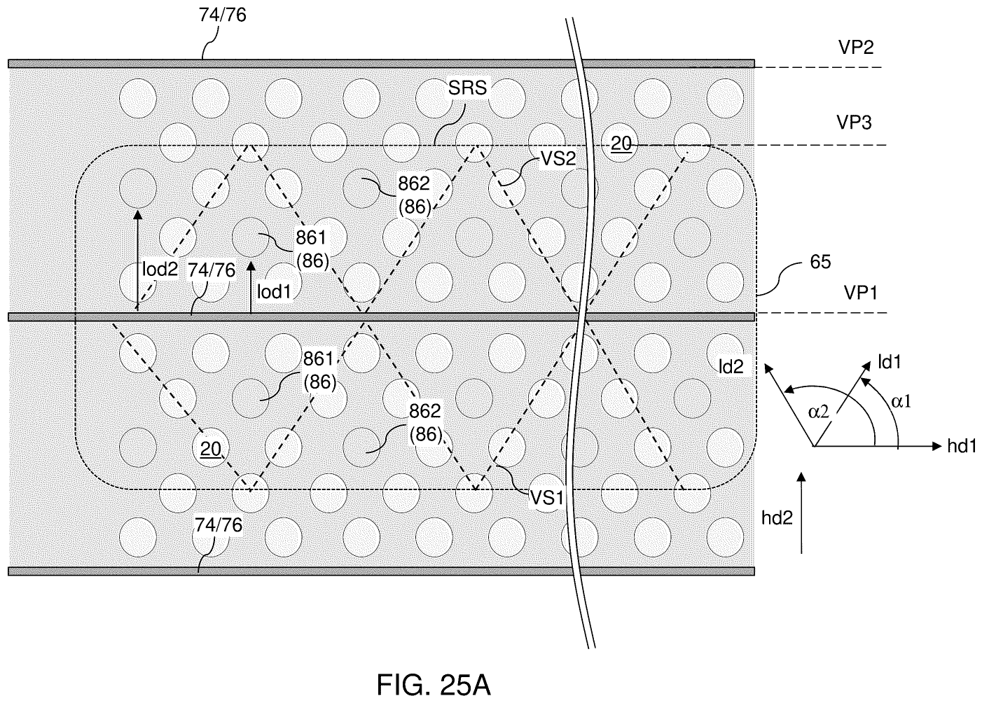

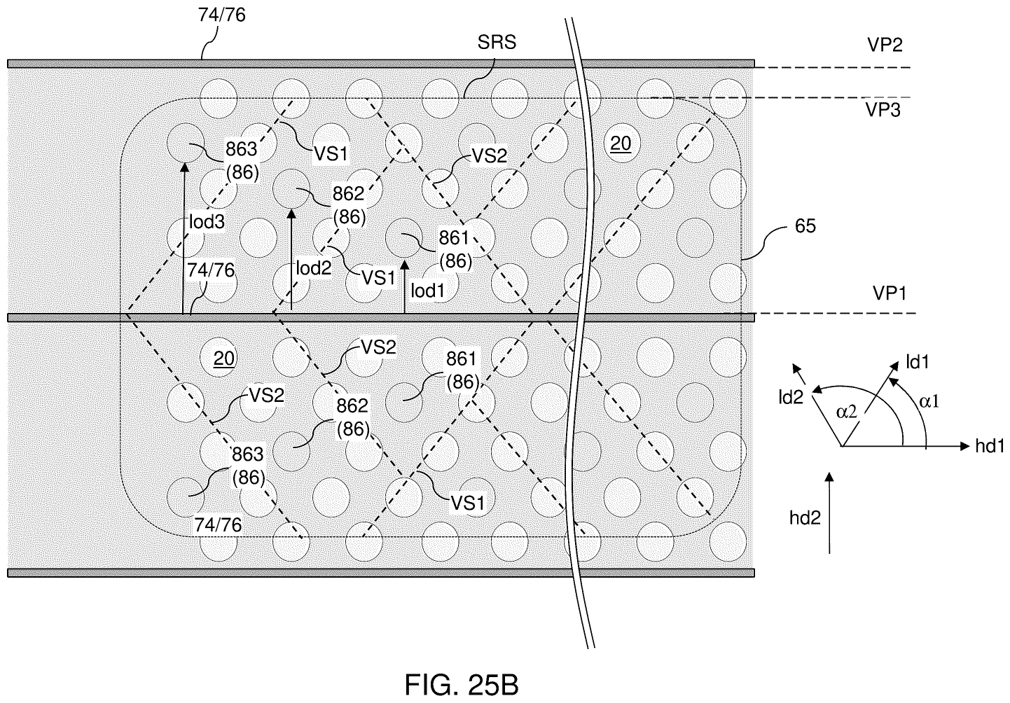

FIGS. 22A-25B illustrate various configurations of the exemplary structure after formation of drain contact via structures 88 and layer contact via structures 86. FIG. 22A is a vertical cross-sectional view of the exemplary structure after formation of the contact via structures (88, 86) according to an embodiment of the present disclosure. FIG. 22B is a top-down cross-sectional view of the exemplary structure of FIG. 22A. The vertical plane A-A′ is the cut plane of the vertical cross-sectional view of FIG. 22A. FIG. 22C is a vertical cross-sectional view of the exemplary structure along the vertical plane C-C′ of FIG. 22B. FIG. 22D is a perspective view of a region of the exemplary structure of FIGS. 22A-22C. FIG. 23A is a top-down view of a first configuration of the exemplary structure. FIG. 23B is a top-down view of a second configuration of the exemplary structure. FIG. 24A is a top-down view of a third configuration of the exemplary structure. FIG. 24B is a vertical cross-sectional view of the third configuration of the exemplary structure along the hinged vertical plane B-B′ of FIG. 24A. FIG. 25A is a top-down view of a fourth configuration of the exemplary structure. FIG. 25B is a top-down view of a fifth configuration of the exemplary structure.

The drain contact via structures 88 can be formed through the contact-level dielectric layer 80 on a respective one of the drain regions 63. For each alternating stack of insulating layers 32 and electrically conductive layers 46, a set of layer contact via structures 86 is provided such that the layer contact via structures 86 contact each of the electrically conductive layers within the alternating stack (32, 46). According to an aspect of the present disclosure, the set of layer contact via structures 86 may comprise multiple rows of layer contact via structures 86 that are laterally offset along the second horizontal direction hd2.

The embodiments shown in FIGS. 22D, 23A and 23B, the set of layer contact via structures 86 contacting the electrically conductive layers 46 in an alternating stack (32, 46) may comprise first contact via structures 861 that are formed through a retro-stepped dielectric material portion 65 on top surfaces of a first subset of the electrically conductive layers 46 within an area of a respective first horizontal surface segment HS1 of the stepped surfaces. The first contact via structures 861 are laterally offset from a first vertical plane VP1 including a first lengthwise sidewall of one of the plurality of lateral isolation trenches 79 by a first lateral offset distance lod1. Further, the set of layer contact via structures 86 may comprise second contact via structures 862 that are formed on top surfaces of a second subset of the electrically conductive layers 46 within an area of a respective second horizontal surface segment HS2 of the stepped surfaces. The second contact via structures 862 are laterally offset from the first vertical plane VP1 by a second lateral offset distance lod2 that is greater than the first lateral offset distance lod1.

Referring to FIGS. 23A, 23B, 24A, 25A and 25B, each alternating stack (32, 46) may comprise a pair of lengthwise sidewalls laterally extending along the first horizontal direction hd1 and located within a first vertical plane VP1 or a second vertical plane VP2. The first vertical plane VP1 and the second vertical plane VP2 laterally extend along the first horizontal direction hd1. In some embodiments, a retro-stepped dielectric material portion 65 may fill a stepped cavity 69 that overlies the stepped surfaces of the alternating stack (32, 46) in the staircase region 200S. The retro-stepped dielectric material portion 65 may comprise a staircase-region sidewall SRS that is located within a third vertical plane VP3 that is located between the first vertical plane VP1 and the second vertical plane VP2. In some configurations, such as the configuration illustrated in FIG. 23B, each retro-stepped dielectric material portion 65 may be located between a respective neighboring pair of lateral isolation trench fill structures (74, 76) such that the retro-stepped dielectric material portion 65 is laterally spaced from the neighboring pair of lateral isolation trench fill structures (74, 76). In this case, another staircase-region sidewall SRS of the retro-stepped dielectric material portion 65 may be located within a fourth vertical plane VP4 that is located between the first vertical plane VP1 and the second vertical plane VP2.

The total number of rows of layer contact via structures 86 vertically extending through a retro-stepped dielectric material portion 65 is an integer greater than 1, which may be 2, 3, 4, 5, 6, etc. FIG. 25B illustrates an embodiment in which the total number of rows of layer contact via structures 86 vertically extending through a retro-stepped dielectric material portion 65 is 3. In this case, the layer contact via structures 86 may comprise third contact via structures 863 that are laterally offset from the first vertical plane VP1 by a third lateral offset distance lod3.

Generally, each horizontal surface segment HS within stepped surfaces of a stepped cavity 69 may be bounded by and may be adjoined to one or more first vertical steps VS1, and may be bounded by and may be adjoined to one or more second vertical steps VS2. FIGS. 23A, 23B, 24A, 24B, and 25A illustrate configurations in which each horizontal surface segment within stepped surfaces of a stepped cavity 69 is adjoined to a single first vertical step VS1 and a single second vertical step VS2. FIG. 25B illustrates a configuration in which some of the horizontal surface segments within stepped surfaces of a stepped cavity 69 are adjoined to a plurality of first vertical steps VS1 and/or a plurality of second vertical steps VS2.

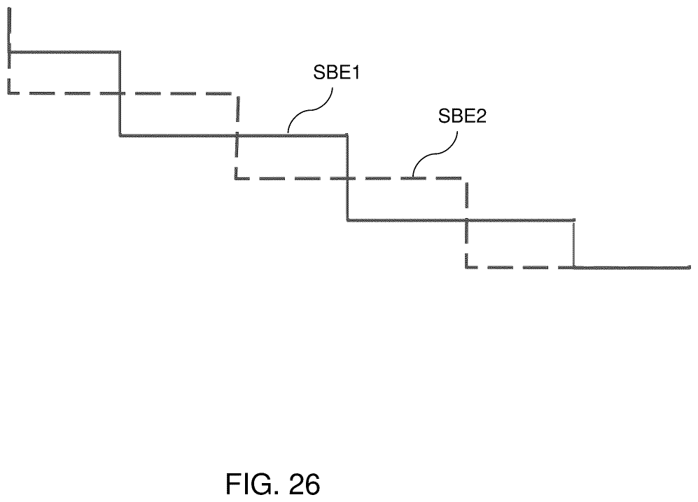

Generally, the non-zero angle tilt of the first lateral direction ld1 and the second lateral direction ld2 relative to the second horizontal direction hd2 causes the two stepped bottom edges of the staircase-region sidewalls SRS of each retro-stepped dielectric material portion 65 to be incongruent relative to each other. FIG. 26 is a schematic diagram illustrating non-congruence of stepped bottom edges (SBE1, SBE2) of the staircase-region sidewalls SRS of a retro-stepped dielectric material portion 65 according to an embodiment of the present disclosure.

Referring collective to FIGS. 1-26 and according to various embodiments of the present disclosure, a three-dimensional memory device is provided, which comprises: an alternating stack (32, 46) of insulating layers 32 and electrically conductive layers 46, the alternating stack (32, 46) having a pair of lengthwise sidewalls that laterally extend along a first horizontal direction hd1 and having stepped surfaces in a staircase region 200S; memory openings 49 vertically extending through a memory array region 100 of the alternating stack (32, 46) in which each layer within the alternating stack (32, 46) is present; and memory opening fill structures 58 in the memory openings 49, wherein each of the memory opening fill structures 58 comprises a vertical stack of memory elements (e.g., portions of the memory film 50) and a vertical semiconductor channel 60, wherein the stepped surfaces in the staircase region comprise first vertical steps VS1 laterally extending along a first lateral direction ld1 which is at an acute angle a1 relative to the first horizontal direction hd1 in a plan view along a vertical direction.

In one embodiment, the stepped surfaces in the staircase region further comprise second vertical steps VS2 laterally extending along a second lateral direction which is at an obtuse angle a2 relative to the first horizontal direction hd1 in the plan view along the vertical direction. In one embodiment, the acute angle a1 ranges from 30 degrees to 80 degrees; and the obtuse angle a2 ranges from 100 degrees to 150 degrees.

In one embodiment, a subset of the second vertical steps VS2 is adjoined to a subset of the first vertical steps VS1. In one embodiment, a subset of the first vertical steps VS1 and a subset of the second vertical steps VS2 are adjoined to a lengthwise sidewall within the pair of lengthwise sidewalls.

In one embodiment, the stepped surfaces further comprise horizontal surface segments HS adjoined to the first vertical steps VS1 and the second vertical steps VS2 of the stepped surfaces; and one of the horizontal surface segments HS comprises a first edge that coincides with a top edge of one of the first vertical steps VS1 and a second edge that coincides with a bottom edge of one of the second vertical steps VS2. In one embodiment, another of the horizontal surface segments HS comprises an edge that coincides with a top edge of another of the first vertical steps VS1 and another edge that coincides with a bottom edge of yet another of the first vertical steps VS1.

In one embodiment, each of the horizontal surface segments HS has a shape of a triangle. In another embodiment, each of the horizontal surface segments HS has a shape of a modified triangle with rounded edges in plan view, in case the horizontal surface segments HS are made using the alternative photoresist pattern shown in FIG. 8B.

In one embodiment, the three-dimensional memory device further comprises first contact via structures 861 contacting top surfaces of a first subset of the electrically conductive layers 46 within an area of a respective first horizontal surface segment of the stepped surfaces, wherein the first contact via structures 861 are laterally offset from a first vertical plane VP1 including a first lengthwise sidewall of the pair of lengthwise sidewalls by a first lateral offset distance lod1. In one embodiment, the three-dimensional memory device further comprises second contact via structures 862 contacting top surfaces of a second subset of the electrically conductive layers 46 within an area of a respective second horizontal surface segment of the stepped surfaces, wherein the second contact via structures 862 are laterally offset from the first vertical plane VP1 by a second lateral offset distance lod2 that is greater than the first lateral offset distance lod1.

In one embodiment, each of the first horizontal surface segments comprises a respective first edge that coincides with a bottom edge of a respective one of the first vertical steps VS1 and comprises a respective second edge that coincides with a top edge of a respective one of the second vertical steps VS2; and each of the second horizontal surface segments comprises a respective first edge that coincides with a bottom edge of a respective one of the second vertical steps VS2 and comprises a respective second edge that coincides with a top surface of a respective one of the first vertical steps VS1. In one embodiment, the three-dimensional memory device comprises third contact via structures 863 contacting top surfaces of a third subset of the electrically conductive layers 46 within an area of a respective third horizontal surface segment of the stepped surfaces, wherein the third contact via structures 863 are laterally offset from the first vertical plane VP1 by a third lateral offset distance lod3 that is greater than the second lateral offset distance lod2.

In one embodiment, each of the first vertical steps VS1 and the second vertical steps VS2 has a respective lateral extent along a second horizontal direction hd2 that is perpendicular to the first horizontal direction hd1 that is less than a lateral spacing between the pair of lengthwise sidewalls.

In one embodiment, the three-dimensional memory device comprises a retro-stepped dielectric material portion 65 overlying the stepped surfaces of the alternating stack (32, 46), wherein the retro-stepped dielectric material portion 65 has a width along a second horizontal direction hd2 that is perpendicular to the first horizontal direction hd1 that is less than a lateral spacing between the pair of lengthwise sidewalls. In one embodiment, the retro-stepped dielectric material portion 65 comprises a first lengthwise sidewall having a first stepped bottom edge SBE1 that is adjoined to first edges of the stepped surfaces of the alternating stack (32, 46), and a second lengthwise sidewall having a second stepped bottom edge SBE2 that is adjoined to second edges of the stepped surfaces of the alternating stack (32, 46); and the second stepped bottom edge SBE2 is not congruent with the first stepped bottom edge SBE1.

In one embodiment, the stepped surfaces comprise horizontal surface segments connecting a respective pair of vertical steps of the first vertical steps VS1 and the second vertical steps VS2 of the stepped surfaces; and a first subset of the horizontal surface segments has a respective lateral extent along the second horizontal direction hd2 that equals the width of the retro-stepped dielectric material portion 65 along the second horizontal direction hd2. In one embodiment, a second subset of the horizontal surface segments has a respective lateral extent along the second horizontal direction hd2 that is less than the width of the retro-stepped dielectric material portion 65 along the second horizontal direction hd2.

In one embodiment, the pair of lengthwise sidewalls of the alternating stack (32, 46) comprise sidewalls of first and second lateral isolation trenches 79 which separate the alternating stack from additional alternating stacks. The first and the second lateral isolation trenches 79 laterally extend along the first horizontal direction hd1.

According to various embodiments of the present disclosure, a three-dimensional memory device having a high-density layout for layer contact via structures 86 is provided. The high-density layout for the layer contact via structures 86 employs vertical steps that are tilted non-orthogonally relative to the general ascension/descension direction of a staircase structure. The vertical steps may have a zigzag pattern in a plan view. The embodiments of the present disclosure reduce the footprint of a staircase region 200S which provides the high-density layout for the layer contact via structures 86. The layer contact via structures 86 may be formed as multiple rows of layer contact via structures 86 that are laterally offset from each other along the bit line direction.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A three-dimensional memory device, comprising:
an alternating stack of insulating layers and electrically conductive layers, the alternating stack having a pair of lengthwise sidewalls that laterally extend along a first horizontal direction and having stepped surfaces in a staircase region;
memory openings vertically extending through a memory array region of the alternating stack in which each layer within the alternating stack is present; and
memory opening fill structures in the memory openings, wherein each of the memory opening fill structures comprises a vertical stack of memory elements and a vertical semiconductor channel,
wherein the stepped surfaces in the staircase region comprise first vertical steps laterally extending along a first lateral direction which is at an acute angle relative to the first horizontal direction in a plan view along a vertical direction.

2. The three-dimensional memory device of claim 1, wherein the stepped surfaces in the staircase region further comprise second vertical steps laterally extending along a second lateral direction which is at an obtuse angle relative to the first horizontal direction in the plan view along the vertical direction.

3. The three-dimensional memory device of claim 2, wherein:
the acute angle ranges from 30 degrees to 80 degrees; and
the obtuse angle ranges from 100 degrees to 150 degrees.

4. The three-dimensional memory device of claim 2, wherein:
a subset of the second vertical steps is adjoined to a subset of the first vertical steps; and
a subset of the first vertical steps and a subset of the second vertical steps are adjoined to a lengthwise sidewall within the pair of lengthwise sidewalls.

5. The three-dimensional memory device of claim 2, wherein:
the stepped surfaces further comprise horizontal surface segments adjoined to the first vertical steps and the second vertical steps of the stepped surfaces; and
one of the horizontal surface segments comprises a first edge that coincides with a top edge of one of the first vertical steps and a second edge that coincides with a bottom edge of one of the second vertical steps; and
another one of the horizontal surface segments comprises an edge that coincides with a top edge of another of the first vertical steps and another edge that coincides with a bottom edge of yet another of the first vertical steps.

6. The three-dimensional memory device of claim 5, wherein each of the horizontal surface segments has a shape of a triangle or a modified triangle with rounded edges in plan view.

7. The three-dimensional memory device of claim 2, further comprising first contact via structures contacting top surfaces of a first subset of the electrically conductive layers within an area of a respective first horizontal surface segment of the stepped surfaces, wherein the first contact via structures are laterally offset from a first vertical plane including a first lengthwise sidewall of the pair of lengthwise sidewalls by a first lateral offset distance.

8. The three-dimensional memory device of claim 7, further comprising second contact via structures contacting top surfaces of a second subset of the electrically conductive layers within an area of a respective second horizontal surface segment of the stepped surfaces, wherein the second contact via structures are laterally offset from the first vertical plane by a second lateral offset distance that is greater than the first lateral offset distance.

9. The three-dimensional memory device of claim 8, wherein:
each of the first horizontal surface segments comprises a respective first edge that coincides with a bottom edge of a respective one of the first vertical steps and comprises a respective second edge that coincides with a top edge of a respective one of the second vertical steps; and
each of the second horizontal surface segments comprises a respective first edge that coincides with a bottom edge of a respective one of the second vertical steps and comprises a respective second edge that coincides with a top surface of a respective one of the first vertical steps.

10. The three-dimensional memory device of claim 8, further comprising third contact via structures contacting top surfaces of a third subset of the electrically conductive layers within an area of a respective third horizontal surface segment of the stepped surfaces, wherein the third contact via structures are laterally offset from the first vertical plane by a third lateral offset distance that is greater than the second lateral offset distance.

11. The three-dimensional memory device of claim 2, wherein each of the first vertical steps and the second vertical steps has a respective lateral extent along a second horizontal direction that is perpendicular to the first horizontal direction that is less than a lateral spacing between the pair of lengthwise sidewalls.

12. The three-dimensional memory device of claim 1, further comprising a retro-stepped dielectric material portion overlying the stepped surfaces of the alternating stack in the staircase region, wherein the retro-stepped dielectric material portion has a width along a second horizontal direction that is perpendicular to the first horizontal direction that is less than a lateral spacing between the pair of lengthwise sidewalls.

13. The three-dimensional memory device of claim 12, wherein:
the retro-stepped dielectric material portion comprises a first lengthwise sidewall having a first stepped bottom edge that is adjoined to first edges of the stepped surfaces of the alternating stack, and a second lengthwise sidewall having a second stepped bottom edge that is adjoined to second edges of the stepped surfaces of the alternating stack; and
the second stepped bottom edge is not congruent with the first stepped bottom edge.

14. The three-dimensional memory device of claim 12, wherein:
the stepped surfaces further comprise horizontal surface segments connecting a respective pair of vertical steps of the first vertical steps and the second vertical steps of the stepped surfaces;
a first subset of the horizontal surface segments has a respective lateral extent along the second horizontal direction that equals the width of the retro-stepped dielectric material portion along the second horizontal direction; and
a second subset of the horizontal surface segments has a respective lateral extent along the second horizontal direction that is less than the width of the retro-stepped dielectric material portion along the second horizontal direction

15. The three-dimensional memory device of claim 1, wherein:
the pair of lengthwise sidewalls comprise sidewalls of first and second lateral isolation trenches which separate the alternating stack from additional alternating stacks; and
the first and the second lateral isolation trenches laterally extend along the first horizontal direction.

16. A method of forming a three-dimensional memory device, comprising:
forming an alternating stack of insulating layers and spacer material layers over a substrate, wherein the spacer material layers are formed as, or are subsequently replaced with, electrically conductive layers;
forming stepped surfaces in a staircase region by patterning the alternating stack, wherein the staircase region is laterally bounded by a staircase-region sidewall laterally extending along a first horizontal direction and having a stepped bottom surface that adjoins edges of stepped surfaces, and wherein the stepped surfaces comprise first vertical steps laterally extending along a first lateral direction which is at an acute angle relative to the first horizontal direction in a plan view along a vertical direction;
forming memory openings through a memory array region of the alternating stack in which each layer within the alternating stack is present; and
forming memory opening fill structures in the memory openings, wherein each of the memory opening fill structures comprises a vertical stack of memory elements and a vertical semiconductor channel.

17. The method of claim 16, further comprising forming a plurality of lateral isolation trenches through the alternating stack, wherein each of the plurality of lateral isolation trenches laterally extends along the first horizontal direction, and wherein the staircase-region sidewall is laterally offset from each of the plurality of lateral isolation trenches.

18. The method of claim 17, wherein the stepped surfaces in the staircase region further comprise second vertical steps laterally extending along a second lateral direction which is at an obtuse angle relative to the first horizontal direction in the plan view along the vertical direction.

19. The method of claim 18, wherein:
the acute angle ranges from 30 degrees to 80 degrees; and
the obtuse angle ranges from 100 degrees to 150 degrees.

20. The method of claim 18, further comprising:
forming first contact via structures on top surfaces of a first subset of the electrically conductive layers within an area of a respective first horizontal surface segment of the stepped surfaces, wherein the first contact via structures are laterally offset from a first vertical plane including a first lengthwise sidewall of one of the plurality of lateral isolation trenches by a first lateral offset distance; and
forming second contact via structures on top surfaces of a second subset of the electrically conductive layers within an area of a respective second horizontal surface segment of the stepped surfaces, wherein the second contact via structures are laterally offset from the first vertical plane by a second lateral offset distance that is greater than the first lateral offset distance.
